(19) United States
(12) Patent Application Publication
(10) Pub. No.: US 2008/0118014 A1
(43) Pub. Date: May 22, 2008

(54) UTILIZING WAKE-UP SIGNALS FOR SYNCHRONIZING MULTIRADIO TIMING

(75) Inventors: Jukka Reunamaki, Tampere (FI); Arto Palin, Viiala (FI); Jussi Ylanen, Lempaala (FI); Ville Pernu, Tampere (FI)

Correspondence Address: MORGAN & FINNEGAN, L.L.P., 3 WORLD FINANCIAL CENTER, NEW YORK, NY, 10281-2101, US

(73) Assignee: NOKIA CORPORATION, Espoo (FI)

(21) Appl. No.: 11/560,561

(22) Filed: Nov. 16, 2006

(51) Int. Cl. H03D 1/00

(52) U.S. Cl. 375/356

(57) ABSTRACT

A system for managing the operation of a plurality of radio modems integrated within the same wireless communication device. In at least one embodiment of the present invention, a control strategy may be employed to manage the operation of a plurality of radio modems and/or wireless mediums. A signal normally used to reactivate or “wake-up” system components in an inactive or sleep mode may also be employed to convey timing and/or control information to the system components of the wireless communication device.

### BACKGROUND OF INVENTION

1. Field of Invention

The present invention relates to a system for managing multiple radio modems integrated within a wireless communication device, and more specifically, to a multiradio control system enabled to create an operational schedule for a plurality of radio modems, wherein control signals normally used only to reactivate or “wake-up” inactive system components are further employed in the synchronization and control of system component behavior.

2. Description of Prior Art

Modern society has quickly adopted, and become reliant upon, handheld devices for wireless communication. For example, cellular telephones continue to proliferate in the global marketplace due to technological improvements in both the quality of the communication and the functionality of the devices. These wireless communication devices (WCDs) have become commonplace for both personal and business use, allowing users to transmit and receive voice, text and graphical data from a multitude of geographic locations. The communication networks utilized by these devices span different frequencies and cover different transmission distances, each having strengths desirable for various applications.

Cellular networks facilitate WCD communication over large geographic areas. These network technologies have commonly been divided by generations, starting in the late 1970s to early 1980s with first generation (1G) analog cellular telephones that provided baseline voice communication, to modern digital cellular telephones. GSM is an example of a widely employed 2G digital cellular network communicating in the 900 MHZ/1.8 GHZ bands in Europe and at 850 MHz and 1.9 GHZ in the United States. This network provides voice communication and also supports the transmission of textual data via the Short Messaging Service (SMS). SMS allows a WCD to transmit and receive text messages of up to 160 characters, while providing data transfer to packet networks, ISDN and POTS users at 9.6 Kbps. The Multimedia Messaging Service (MMS), an enhanced messaging system allowing for the transmission of sound, graphics and video files in addition to simple text, has also become available in certain devices. Soon emerging technologies such as Digital Video Broadcasting for Handheld Devices (DVB-H) will make streaming digital video, and other similar content, available via direct transmission to a WCD. While long-range communication networks like GSM are a well-accepted means for transmitting and receiving data, due to cost, traffic and legislative concerns, these networks may not be appropriate for all data applications.

Short-range wireless networks provide communication solutions that avoid some of the problems seen in large cellular networks. Bluetooth™ is an example of a short-range wireless technology quickly gaining acceptance in the marketplace. A Bluetooth™ enabled WCD transmits and receives data at a rate of 720 Kbps within a range of 10 meters, and may transmit up to 100 meters with additional power boosting. A user does not actively instigate a Bluetooth™ network. Instead, a plurality of devices within operating range of each other may automatically form a network group called a “piconet”. Any device may promote itself to the master of the piconet, allowing it to control data exchanges with up to seven “active” slaves and 255 “parked” slaves. Active slaves exchange data based on the clock timing of the master. Parked slaves monitor a beacon signal in order to stay synchronized with the master. These devices continually switch between various active communication and power saving modes in order to transmit data to other piconet members. In addition to Bluetooth™ other popular short-range wireless networks include WLAN (of which “Wi-Fi” local access points communicating in accordance with the IEEE 802.11 standard, is an example), WUSB, UWB, ZigBee (802.15.4, 802.15.4a), and UHF RFID. All of these wireless mediums have features and advantages that make them appropriate for various applications.

More recently, manufacturers have also begun to incorporate various resources for providing enhanced functionality in WCDs (e.g., components and software for performing close-proximity wireless information exchanges). Sensors and/or scanners may be used to read visual or electronic information into a device. A transaction may involve a user holding their WCD in proximity to a target, aiming their WCD at an object (e.g., to take a picture) or sweeping the device over a printed tag or document. Near Field communication (NFC) technologies include machine-readable mediums such as radio frequency identification (RFID), Infra-red (IR) communication, optical character recognition (OCR) and various other types of visual, electronic and magnetic scanning are used to quickly input desired information into the WCD without the need for manual entry by a user.

Device manufacturers are continuing to incorporate as many of the previously indicated exemplary communication features as possible into wireless communication devices in an attempt to bring powerful, “do-all” devices to market. Devices incorporating long-range, short-range and NFC resources also often include multiple mediums for each category. This may allow a communication device to flexibly adjust to its surroundings, for example, communicating both with a WLAN access point and a Bluetooth™ communication accessory, possibly at the same time.

Given the large array communication features that may be compiled into a single device, it is foreseeable that a user will need to employ a WCD to its full potential when replacing other productivity related devices. For example, a user may use a high powered WCD to replace traditional tools such as individual phones, facsimile machines, computers, storage media, etc. which tend to be more cumbersome to both integrate and transport. In at least one use scenario, a WCD may be communicating simultaneously over numerous different wireless mediums. A user may utilize multiple peripheral Bluetooth™ devices (e.g., a headset and a keyboard) while having a voice conversation over GSM and interacting with a WLAN access point in order to access the Internet. Problems may occur when these concurrent transactions cause interference with each other. Even if a communication medium does not have an identical operating frequency as another medium, a radio modem may cause extraneous interference to another medium. Further, it is possible for the combined effects of two or more simultaneously operating radios to create intermodulation effects to another bandwidth due to harmonic effects. These disturbances may cause errors resulting in the required retransmission of lost packets, and the overall degradation of performance for one or more communication mediums.

Evolving strategies for regulating air time between two or more radio modems contained in the same device often require a centralized (as a single component or distributed among various components) communication control enforcing an operational schedule for all active radio modems, the regulation of which helps to reduce the possibility of communication collisions between these active radio modems. However, in order for the operational schedule to be effective, the interplay of modem activity must be precisely controlled. This precision may be derived from the communication controller being synchronized with the modem by, for example, knowing the communication backlog and the timing patterns of the various active radio modems.

In a system such as previously set forth, precision related problems are foreseeable because the timing in radio modems is frequently changing. For example, radio modems may move from an active to inactive (or sleep) mode as communication activity changes, or may jump from one wireless access point to another via handoff (handover). A solution for accommodating a timing change would be to add new functionality to the system for requesting/providing the latest timing information from the radio modem. In a largely software based system this may not pose a problem. However, in a resource constrained hard-coded chipset, the addition of any functionality, let alone I/O functionality, may require a redesign, a higher pin-count package, or to consolidate other functionality. A chip redesign may further trigger the adding of new traces/layers to circuit board(s). As a result, any hardware redesign would potentially add great expense to the system, making this type of change prohibitive.

What is therefore needed is a management system for regulating radio modems utilizing possibly conflicting wireless communication mediums. This system should further include the ability to request synchronization information and/or to implement control in various system components without the need to implement a hardware redesign to a existing multiradio communication control interface

### SUMMARY OF INVENTION

The present invention includes at least a method, device, computer program, multiradio controller and radio modem for managing the operation of a plurality of radio modems integrated within the same WCD. In at least one embodiment of the present invention, a control strategy may be employed to manage the operation of a plurality of radio modems and/or wireless mediums. A signal normally used to reactivate or “wake-up” system components in an inactive or sleep mode may also be employed to convey timing and/or control information to the system components.

At least one embodiment of the present invention may, while utilizing wake-up signals for their present function, further enhance the interpretation of these signals in the recipient to provide new information transmission capabilities. More specifically, a system component may utilize these signals in the usual fashion, such as to trigger a reactivation, but may further be enabled to interpret control and/or synchronization information from these signals in order to provide current timing and/or control information for controlling a system component.

For timing signals utilized to wake-up a communication controller, information in the wake-up signal may include a series of slot/frame border indicators that may be used by a controller in synchronizing to the timing of a radio modem. Further, in an exemplary reverse situation, a wake-up signal for a radio modem may also include information indicating that a radio modem should temporarily halt operations in a specified amount of time, for example, because a new operational schedule is about to be distributed by the communications controller.

### DESCRIPTION OF DRAWINGS

The invention will be further understood from the following detailed description of a preferred embodiment, taken in conjunction with appended drawings, in which:

FIG. 1 discloses an exemplary wireless operational environment, including wireless communication mediums of different effective range.

FIG. 2 discloses a modular description of an exemplary wireless communication device usable with at least one embodiment of the present invention.

FIG. 3 discloses an exemplary structural description of the wireless communication device previously described in FIG. 2.

FIG. 4 discloses an exemplary operational description of a wireless communication device utilizing a wireless communication medium in accordance with at least one embodiment of the present invention.

FIG. 5 discloses an operational example wherein interference occurs when utilizing multiple radio modems simultaneously within the same wireless communication device.

FIG. 6A discloses an exemplary structural description of a wireless communication device including a multiradio controller in accordance with at least one embodiment of the present invention.

FIG. 6B discloses a more detailed structural diagram of FIG. 6A including the multiradio controller and the radio modems.

FIG. 6C discloses an exemplary operational description of a wireless communication device including a multiradio controller in accordance with at least one embodiment of the present invention.

FIG. 7A discloses an exemplary structural description of a wireless communication device including a multiradio control system in accordance with at least one embodiment of the present invention.

FIG. 7B discloses a more detailed structural diagram of FIG. 7A including the multiradio control system and the radio modems.

FIG. 7C discloses an exemplary operational description of a wireless communication device including a multiradio control system in accordance with at least one embodiment of the present invention.

FIG. 8A discloses an exemplary structural description of a wireless communication device including a distributed multiradio control system in accordance with at least one embodiment of the present invention.

FIG. 8B discloses a more detailed structural diagram of FIG. 8A including the distributed multiradio control system and the radio modems.

FIG. 8C discloses an exemplary operational description of a wireless communication device including a distributed multiradio control system in accordance with at least one embodiment of the present invention.

FIG. 9A discloses an exemplary structural description of a wireless communication device including a distributed multiradio control system in accordance with an alternative embodiment of the present invention.

FIG. 9B discloses a more detailed structural diagram of FIG. 9A including the distributed multiradio control system and the radio modems.

FIG. 9C discloses an exemplary operational description of a wireless communication device including a distributed multiradio control system in accordance with the alternative embodiment of the present invention disclosed in FIG. 9A.

FIG. 10 discloses an exemplary information packet usable with at least one embodiment of the present invention.

FIG. 11A discloses an example of wake-up signals that may be transmitted between system components within a wireless communication device in accordance with at least one embodiment of the present invention.

FIG. 11B discloses exemplary original and modified wake-up signals that may be transmitted from a radio modem to a communication controller in a wireless communication device in accordance with at least one embodiment of the present invention.

FIG. 11C discloses exemplary original and modified wake-up signals that may be transmitted from a communication controller to a radio modem in a wireless communication device in accordance with at least one embodiment of the present invention.

FIG. 12 discloses a flowchart explaining an exemplary process by which communication signals are transmitted, interpreted and/or implemented in accordance with at least one embodiment of the present invention.

FIG. 13 discloses an alternative communication configuration, wherein a control entity and a radio modem may be directly coupled in accordance with at least one embodiment of the present invention.

FIG. 14 discloses an alternative communication configuration, wherein a control entity and radio modems may be directly coupled in accordance with at least one embodiment of the present invention.

### DESCRIPTION OF PREFERRED EMBODIMENT

While the invention has been described in preferred embodiments, various changes can be made therein without departing from the spirit and scope of the invention, as described in the appended claims.

### I. Wireless Communication Over Different Communication Networks

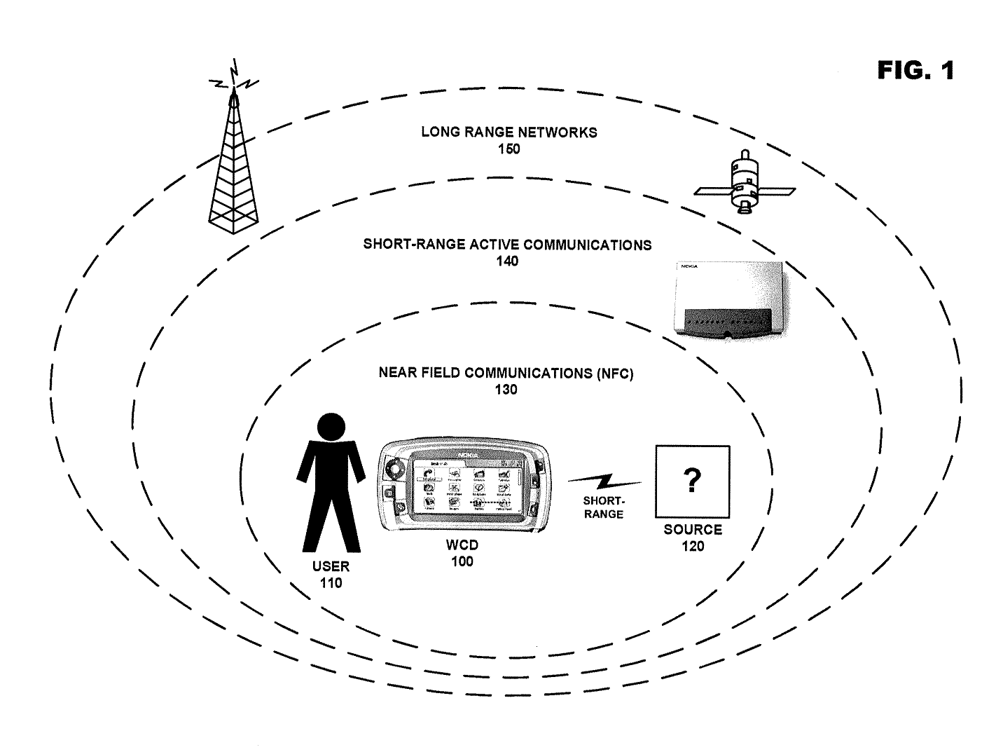

A WCD may both transmit and receive information over a wide array of wireless communication networks, each with different advantages regarding speed, range, quality (error correction), security (encoding), etc. These characteristics will dictate the amount of information that may be transferred to a receiving device, and the duration of the information transfer. FIG. 1 includes a diagram of a WCD and how it interacts with various types of wireless networks.

In the example pictured in FIG. 1, user 110 possesses WCD 100. This device may be anything from a basic cellular handset to a more complex device such as a wirelessly enabled palmtop or laptop computer. Near Field Communication (NFC) 130 includes various transponder-type interactions wherein normally only the scanning device requires its own power source. WCD 100 scans source 120 via short-range communication. A transponder in source 120 may use the energy and/or clock signal contained within the scanning signal, as in the case of RFID communication, to respond with data stored in the transponder. These types of technologies usually have an effective transmission range on the order of ten feet, and may be able to deliver stored data in amounts from a bit to over a megabit (or 125 Kbytes) relatively quickly. These features make such technologies well suited for identification purposes, such as to receive an account number for a public transportation provider, a key code for an automatic electronic door lock, an account number for a credit or debit transaction, etc.

The transmission range between two devices may be extended if both devices are capable of performing powered communication. Short-range active communication 140 includes applications wherein the sending and receiving devices are both active. An exemplary situation would include user 110 coming within effective transmission range of a Bluetooth™, WLAN, UWB, WUSB, etc. access point. In the case of Bluetooth™, a network may automatically be established to transmit information to WCD 100 possessed by user 110. This data may include information of an informative, educational or entertaining nature. The amount of information to be conveyed is unlimited, except that it must all be transferred in the time when user 110 is within effective transmission range of the access point. Due to the higher complexity of these wireless networks, additional time is also required to establish the initial connection to WCD 100, which may be increased if many devices are queued for service in the area proximate to the access point. The effective transmission range of these networks depends on the technology, and may be from some 30 ft. to over 300 ft. with additional power boosting.

Long-range networks 150 are used to provide virtually uninterrupted communication coverage for WCD 100. Land-based radio stations or satellites are used to relay various communication transactions worldwide. While these systems are extremely functional, the use of these systems is often charged on a per-minute basis to user 110, not including additional charges for data transfer (e.g., wireless Internet access). Further, the regulations covering these systems may cause additional overhead for both the users and providers, making the use of these systems more cumbersome.

### II. Wireless Communication Device

As previously described, the present invention may be implemented using a variety of wireless communication equipment. Therefore, it is important to understand the communication tools available to user 110 before exploring the present invention. For example, in the case of a cellular telephone or other handheld wireless devices, the integrated data handling capabilities of the device play an important role in facilitating transactions between the transmitting and receiving devices.

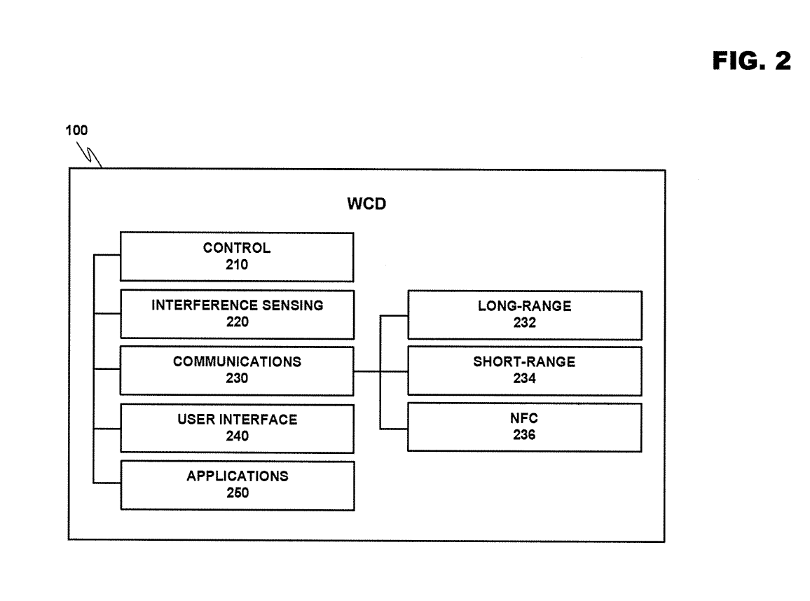

FIG. 2 discloses an exemplary modular layout for a wireless communication device usable with the present invention. WCD 100 is broken down into modules representing the functional aspects of the device. These functions may be performed by the various combinations of software and/or hardware components discussed below.

Control module 210 regulates the operation of the device. Inputs may be received from various other modules included within WCD 100. For example, interference sensing module 220 may use various techniques known in the art to sense sources of environmental interference within the effective transmission range of the wireless communication device. Control module 210 interprets these data inputs, and in response, may issue control commands to the other modules in WCD 100.

Communications module 230 incorporates all of the communication aspects of WCD 100. As shown in FIG. 2, communications module 230 may include, for example, long-range communications module 232, short-range communications module 234 and NFC module 236. Communications module 230 may utilize one or more of these sub-modules to receive a multitude of different types of communication from both local and long distance sources, and to transmit data to recipient devices within the transmission range of WCD 100. Communications module 230 may be triggered by control module 210, or by control resources local to the module responding to sensed messages, environmental influences and/or other devices in proximity to WCD 100.

User interface module 240 includes visual, audible and tactile elements which allow the user 110 to receive data from, and enter data into, the device. The data entered by user 110 may be interpreted by control module 210 to affect the behavior of WCD 100. User-inputted data may also be transmitted by communications module 230 to other devices within effective transmission range. Other devices in transmission range may also send information to WCD 100 via communications module 230, and control module 210 may cause this information to be transferred to user interface module 240 for presentment to the user.

Applications module 250 incorporates all other hardware and/or software applications on WCD 100. These applications may include sensors, interfaces, utilities, interpreters, data applications, etc., and may be invoked by control module 210 to read information provided by the various modules and in turn supply information to requesting modules in WCD 100.

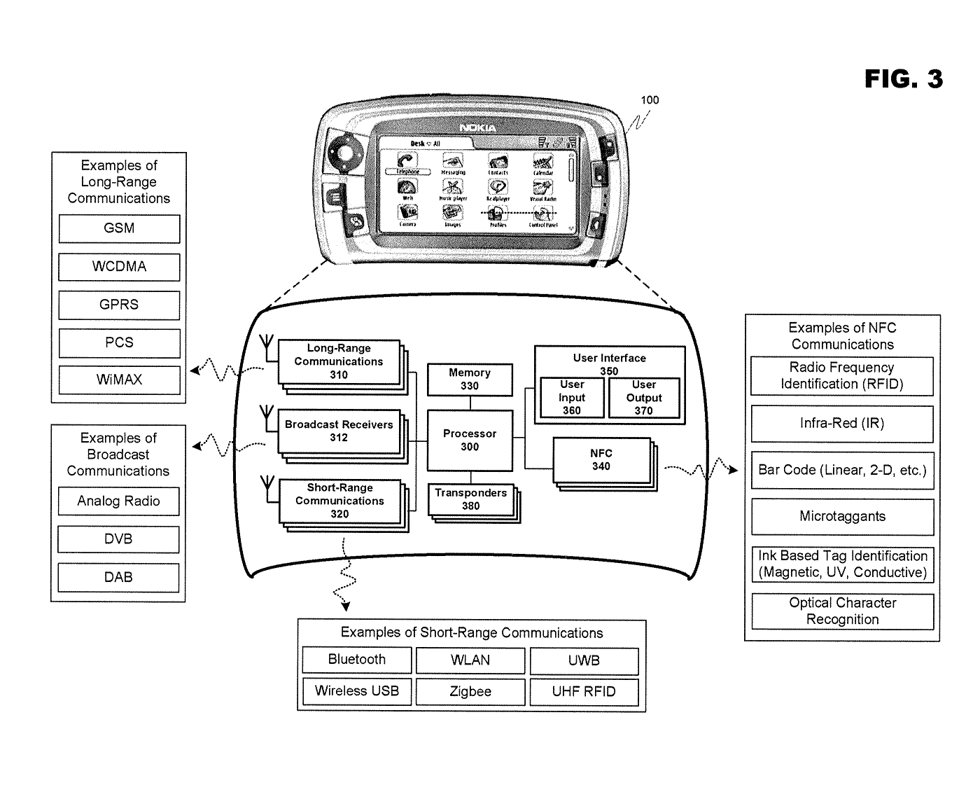

FIG. 3 discloses an exemplary structural layout of WCD 100 according to an embodiment of the present invention that may be used to implement the functionality of the modular system previously described in FIG. 2. Processor 300 controls overall device operation. As shown in FIG. 3, processor 300 is coupled to one or more communications sections 310, 320 and 340. Processor 300 may be implemented with one or more microprocessors that are each capable of executing software instructions stored in memory 330.

Memory 330 may include random access memory (RAM), read only memory (ROM), and/or flash memory, and stores information in the form of data and software components (also referred to herein as modules). The data stored by memory 330 may be associated with particular software components. In addition, this data may be associated with databases, such as a bookmark database or a business database for scheduling, email, etc.

The software components stored by memory 330 include instructions that can be executed by processor 300. Various types of software components may be stored in memory 330. For instance, memory 330 may store software components that control the operation of communication sections 310, 320 and 340. Memory 330 may also store software components including a firewall, a service guide manager, a bookmark database, user interface manager, and any communication utilities modules required to support WCD 100.

Long-range communications 310 performs functions related to the exchange of information over large geographic areas (such as cellular networks) via an antenna. These communication methods include technologies from the previously described 1G to 3G. In addition to basic voice communication (e.g., via GSM), long-range communications 310 may operate to establish data communication sessions, such as General Packet Radio Service (GPRS) sessions and/or Universal Mobile Telecommunications System (UMTS) sessions. Also, long-range communications 310 may operate to transmit and receive messages, such as short messaging service (SMS) messages and/or multimedia messaging service (MMS) messages.

As a subset of long-range communications 310, or alternatively operating as an independent module separately connected to processor 300, transmission receiver 312 allows WCD 100 to receive transmission messages via mediums such as Digital Video Broadcast for Handheld Devices (DVB-H). These transmissions may be encoded so that only certain designated receiving devices may access the transmission content, and may contain text, audio or video information. In at least one example, WCD 100 may receive these transmissions and use information contained within the transmission signal to determine if the device is permitted to view the received content.

Short-range communications 320 is responsible for functions involving the exchange of information across short-range wireless networks. As described above and depicted in FIG. 3, examples of such short-range communications 320 are not limited to Bluetooth™, WLAN, UWB and Wireless USB connections. Accordingly, short-range communications 320 performs functions related to the establishment of short-range connections, as well as processing related to the transmission and reception of information via such connections.

NFC 340, also depicted in FIG. 3, may provide functionality related to the short-range scanning of machine-readable data. For example, processor 300 may control components in NFC 340 to generate RF signals for activating an RFID transponder, and may in turn control the reception of signals from an RFID transponder. Other short-range scanning methods for reading machine-readable data that may be supported by the NFC 340 are not limited to IR communication, linear and 2-D (e.g., QR) bar code readers (including processes related to interpreting UPC labels), and optical character recognition devices for reading magnetic, UV, conductive or other types of coded data that may be provided in a tag using suitable ink. In order for the NFC 340 to scan the aforementioned types of machine-readable data, the input device may include optical detectors, magnetic detectors, CCDs or other sensors known in the art for interpreting machine-readable information.

As further shown in FIG. 3, user interface 350 is also coupled to processor 300. User interface 350 facilitates the exchange of information with a user. FIG. 3 shows that user interface 350 includes a user input 360 and a user output 370. User input 360 may include one or more components that allow a user to input information. Examples of such components include keypads, touch screens, and microphones. User output 370 allows a user to receive information from the device. Thus, user output portion 370 may include various components, such as a display, light emitting diodes (LED), tactile emitters and one or more audio speakers. Exemplary displays include liquid crystal displays (LCDs), and other video displays.

WCD 100 may also include one or more transponders 380. This is essentially a passive device that may be programmed by processor 300 with information to be delivered in response to a scan from an outside source. For example, an RFID scanner mounted in an entryway may continuously emit radio frequency waves. When a person with a device containing transponder 380 walks through the door, the transponder is energized and may respond with information identifying the device, the person, etc. In addition, a scanner may be mounted (e.g., as previously discussed above with regard to examples of NFC 340) in WCD 100 so that it can read information from other transponders in the vicinity.

Hardware corresponding to communications sections 310, 312, 320 and 340 provide for the transmission and reception of signals. Accordingly, these portions may include components (e.g., electronics) that perform functions, such as modulation, demodulation, amplification, and filtering. These portions may be locally controlled, or controlled by processor 300 in accordance with software communication components stored in memory 330.

The elements shown in FIG. 3 may be constituted and coupled according to various techniques in order to produce the functionality described in FIG. 2. One such technique involves coupling separate hardware components corresponding to processor 300, communications sections 310, 312 and 320, memory 330, NFC 340, user interface 350, transponder 380, etc. through one or more bus interfaces (which may be wired or wireless bus interfaces). Alternatively, any and/or all of the individual components may be replaced by an integrated circuit in the form of a programmable logic device, gate array, ASIC, multi-chip module, etc. programmed to replicate the functions of the stand-alone devices. In addition, each of these components is coupled to a power source, such as a removable and/or rechargeable battery (not shown).

The user interface 350 may interact with a communication utilities software component, also contained in memory 330, which provides for the establishment of service sessions using long-range communications 310 and/or short-range communications 320. The communication utilities component may include various routines that allow the reception of services from remote devices according to mediums such as the Wireless Application Medium (WAP), Hypertext Markup Language (HTML) variants like Compact HTML (CHTML), etc.

### III. Exemplary Operation of a Wireless Communication Device Including Potential Interference Problems Encountered.

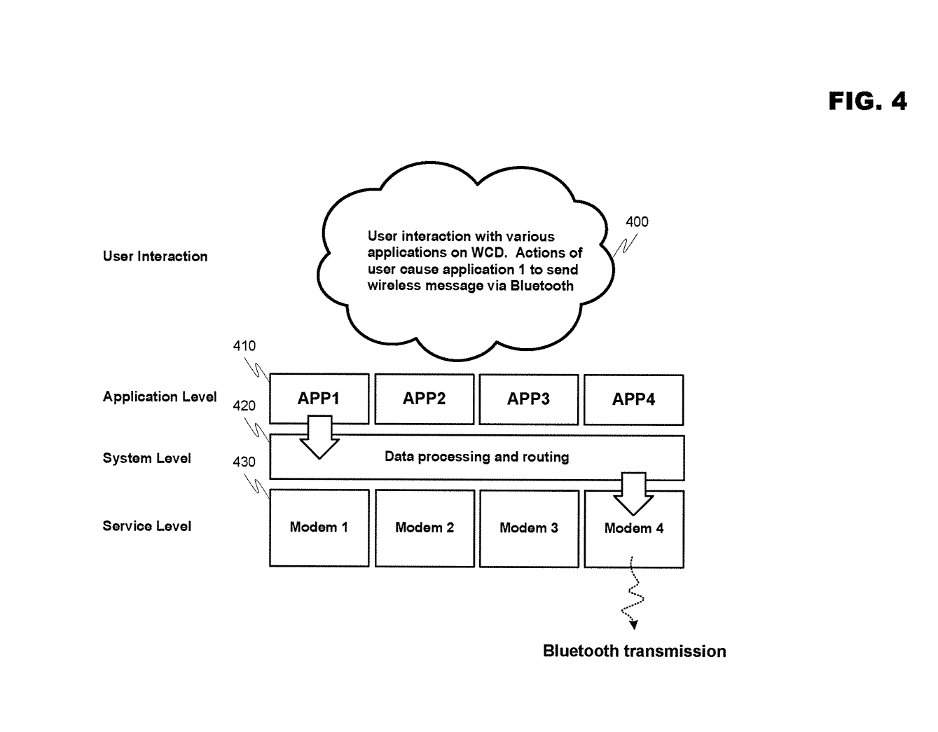

FIG. 4 discloses a stack approach to understanding the operation of a WCD in accordance with at least one embodiment of the present invention. At the top level 400, user 110 interacts with WCD 100. The interaction involves user 110 entering information via user input 360 and receiving information from user output 370 in order to activate functionality in application level 410. In the application level, programs related to specific functionality within the device interact with both the user and the system level. These programs include applications for visual information (e.g., web browser, DVB-H receiver, etc.), audio information (e.g., cellular telephone, voice mail, conferencing software, DAB or analog radio receiver, etc.), recording information (e.g., digital photography software, word processing, scheduling, etc.) or other information processing. Actions initiated at application level 410 may require information to be sent from or received into WCD 100. In the example of FIG. 4, data is requested to be sent to a recipient device via Bluetooth™ communication. As a result, application level 410 may then call resources in the system level to initiate the required processing and routing of data.

System level 420 processes data requests and routes the data for transmission. Processing may include, for example, calculation, translation, conversion and/or packetizing the data. The information may then be routed to an appropriate communication resource in the service level. If the desired communication resource is active and available in the service level 430, the packets may be routed to a radio modem for delivery via wireless transmission. There may be a plurality of modems operating using different wireless mediums. For example, in FIG. 4, modem 4 is activated and able to send packets using Bluetooth™ communication. However, a radio modem (as a hardware resource) need not be dedicated only to a specific wireless medium, and may be used for different types of communication depending on the requirements of the wireless medium and the hardware characteristics of the radio modem.

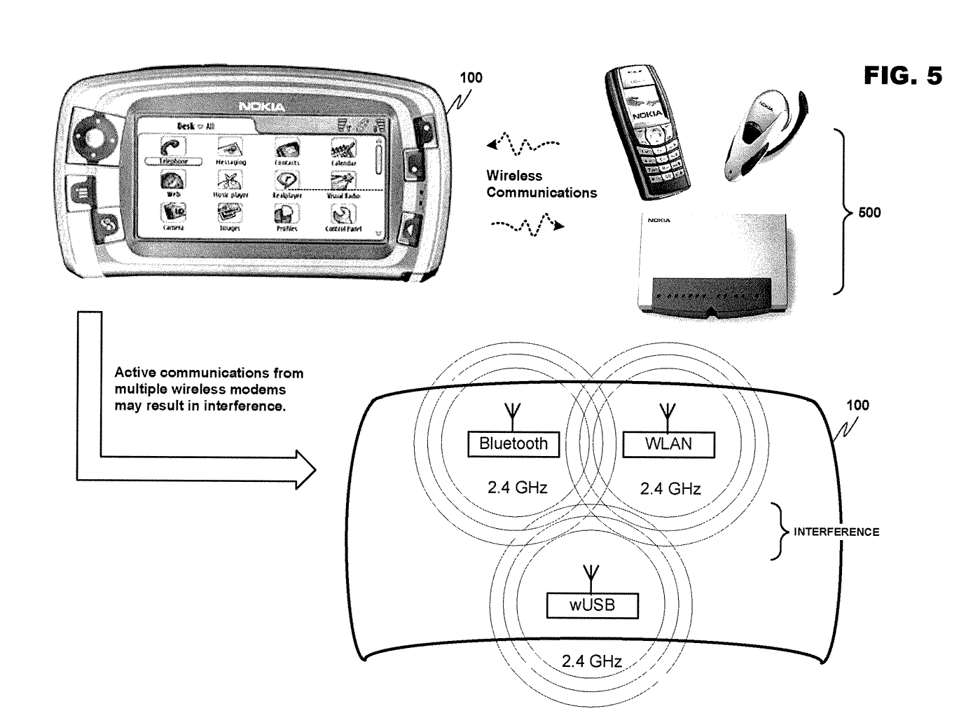

FIG. 5 discloses a situation wherein the above described exemplary operational process may cause more than one radio modem to become active. In this case, WCD 100 is both transmitting and receiving information via wireless communication over a multitude of mediums. WCD 100 may be interacting with various secondary devices such as those grouped at 500. For example, these devices may include cellular handsets communicating via long-range wireless communication like GSM, wireless headsets communicating via Bluetooth™, Internet access points communicating via WLAN, etc.

Problems may occur when some or all of these communications are carried on simultaneously. As further shown in FIG. 5, multiple modems operating simultaneously may cause interference for each other. Such a situation may be encountered when WCD 100 is communicating with more than one external device (as previously described). In an exemplary extreme case, devices with modems simultaneously communicating via Bluetooth™, WLAN and wireless USB would encounter substantial overlap since all of these wireless mediums operate in the 2.4 GHz band. The interference, shown as an overlapping portion of the fields depicted in FIG. 5, would cause packets to be lost and the need for retransmission of these lost packets. Retransmission requires that future time slots be used to retransmit lost information, and therefore, overall communication performance will at least be reduced, if the signal is not lost completely. The present invention, in at least one embodiment, seeks to manage problematic situations where possibly conflicting communications may be occurring simultaneously so that interference is minimized or totally avoided, and as a result, speed and quality are maximized.

### IV. A Wireless Communication Device Including a Multiradio Controller.

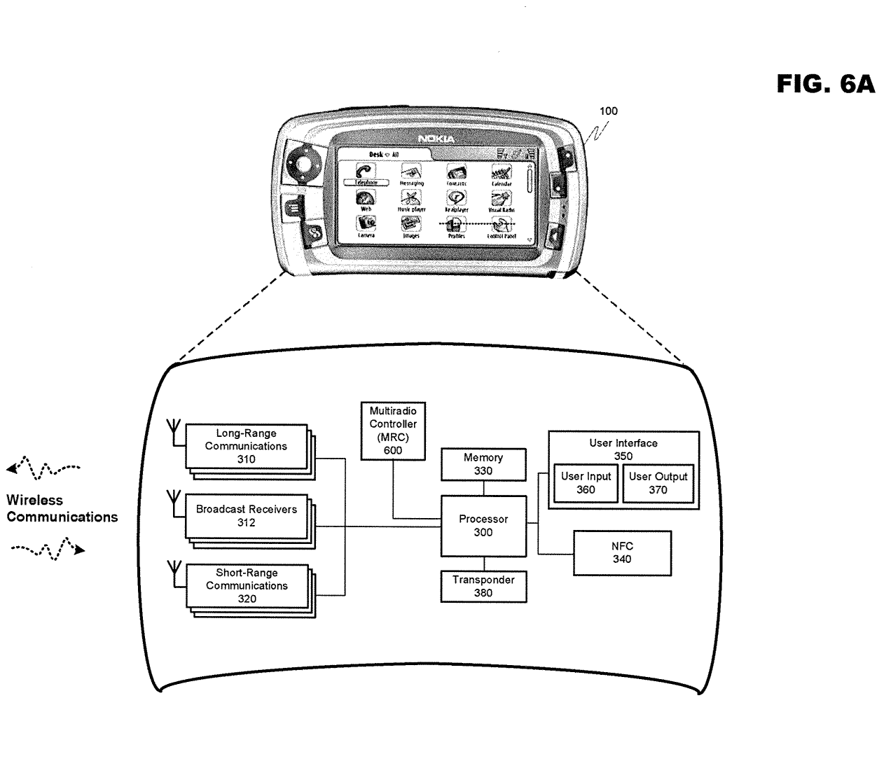

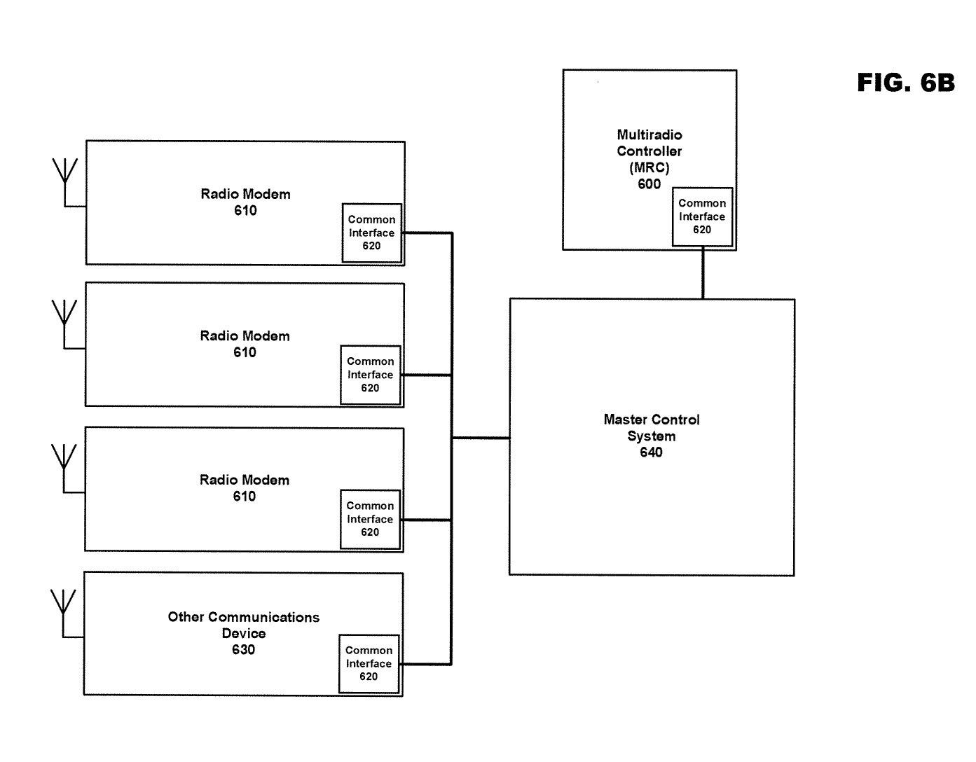

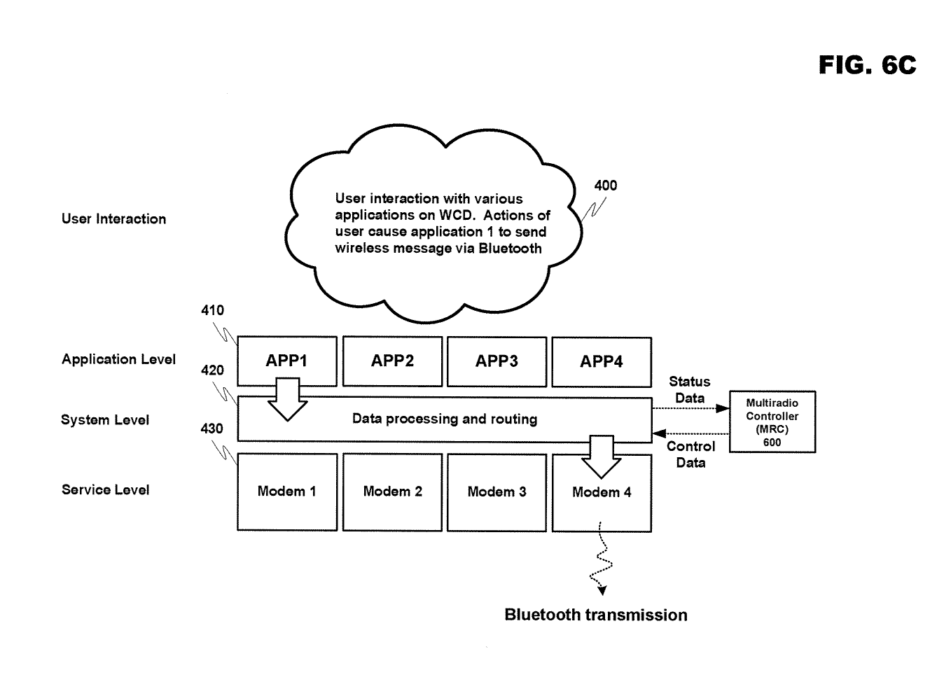

In an attempt to better manage communication in WCD 100, an additional controller dedicated to managing wireless communication may be introduced. WCD 100, as pictured in FIG. 6A, includes a multiradio controller (MRC) 600 in accordance with at least one embodiment of the present invention. MRC 600 is coupled to the master control system of WCD 100. This coupling enables MRC 600 to communicate with radio modems or other similar devices in communications modules 310 312, 320 and 340 via the master operating system of WCD 100.

FIG. 6B discloses in detail at least one embodiment of WCD 100, which may include multiradio controller (MRC) 600 introduced in FIG. 6A in accordance with at least one embodiment of the present invention. MRC 600 includes common interface 620 by which information may be sent or received through master control system 640. Further, each radio modem 610 or similar communication device 630, for example an RFID scanner for scanning machine-readable information, may also include some sort of common interface 620 for communicating with master control system 640. As a result, all information, commands, etc. occurring between radio modems 610, similar devices 630 and MRC 600 are conveyed by the communication resources of master control system 640. The possible effect of sharing communication resources with all the other functional modules within WCD 100 will be discussed with respect to FIG. 6C.

FIG. 6C discloses an operational diagram similar to FIG. 4 including the effect of MRC 600 in accordance with at least one embodiment of the present invention. In this system MRC 600 may receive operational data from the master operating system of WCD 100, concerning for example applications running in application level 410, and status data from the various radio communication devices in service level 430. MRC 600 may use this information to issue scheduling commands to the communication devices in service level 430 in an attempt to avoid communication problems. However, problems may occur when the operations of WCD 100 are fully employed. Since the various applications in application level 410, the operating system in system level 420, the communication devices in service level 430 and MRC 600 must all share the same communication system, delays may occur when all aspects of WCD 100 are trying to communicate on the common interface system 620. As a result, delay sensitive information regarding both communication resource status information and radio modem 610 control information may become delayed, nullifying any beneficial effect from MRC 600. Therefore, a system better able to handle the differentiation and routing of delay sensitive information is required if the beneficial effect of MRC 600 is to be realized.

### V. A Wireless Communication Device Including a Multiradio Control System.

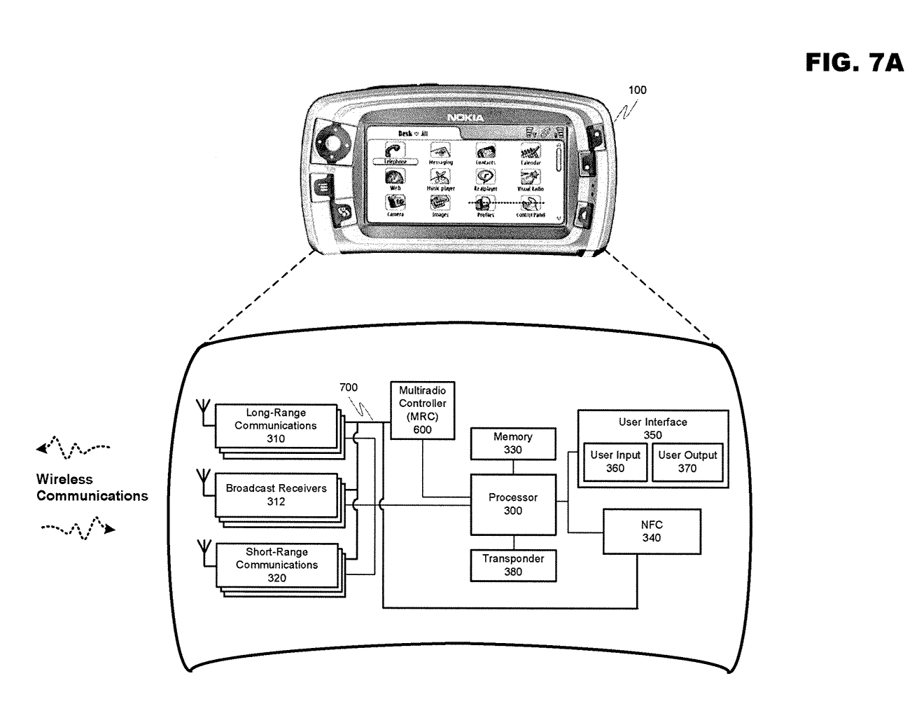

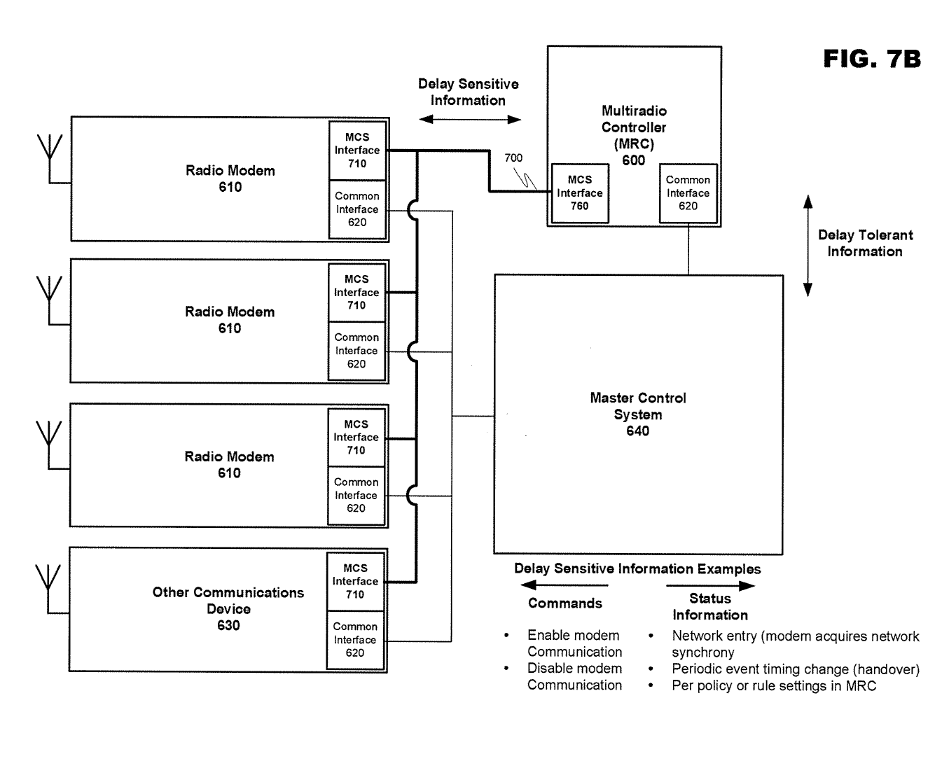

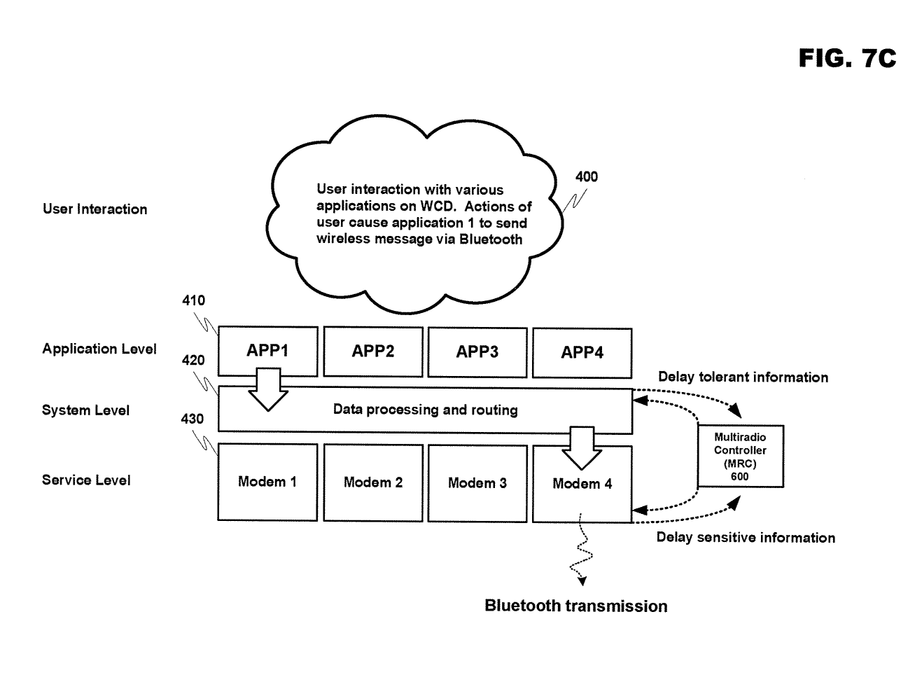

FIG. 7A introduces MRC 600 as part of a multiradio control system (MCS) 700 in WCD 100 in accordance with at least one embodiment of the present invention. MCS 700 directly links the communication resources of modules 310, 312, 320 and 340 to MRC 600. MCS 700 may provide a dedicated low-traffic communication structure for carrying delay sensitive information both to and from MRC 600.

Additional detail is shown in FIG. 7B. MCS 700 forms a direct link between MRC 600 and the communication resources of WCD 100. This link may be established by a system of dedicated MCS interfaces 710 and 760. For example, MCS interface 760 may be coupled to MRC 600. MCS Interfaces 710 may connect radio modems 610 and other similar communication devices 630 to MCS 700 in order to form an information conveyance for allowing delay sensitive information to travel to and from MRC 600. In this way, the abilities of MRC 600 are no longer influenced by the processing load of master control system 640. As a result, any information still communicated by master control system 640 to and from MRC 600 may be deemed delay tolerant, and therefore, the actual arrival time of this information does not substantially influence system performance. On the other hand, all delay sensitive information is directed to MCS 700, and therefore is insulated from the loading of the master control system.

The effect of MCS 700 is seen in FIG. 7C in accordance with at least one embodiment of the present invention. Information may now be received in MRC 600 from at least two sources. System level 420 may continue to provide information to MRC 600 through master control system 640. In addition, service level 430 may specifically provide delay sensitive information conveyed by MCS 700. MRC 600 may distinguish between these two classes of information and act accordingly. Delay tolerant information may include information that typically does not change when a radio modem is actively engaged in communication, such as radio mode information (e.g., GPRS, Bluetooth™, WLAN, etc.), priority information that may be defined by user settings, the specific service the radio is driving (QoS, real time/non real time), etc. Since delay tolerant information changes infrequently, it may be delivered in due course by master control system 640 of WCD 100. Alternatively, delay sensitive (or time sensitive) information includes at least modem operational information that frequently changes during the course of a wireless connection, and therefore, requires immediate update. As a result, delay sensitive information may need to be delivered directly from the plurality of radio modems 610 through the MCS interfaces 710 and 760 to MRC 600, and may include radio modem synchronization information. Delay sensitive information may be provided in response to a request by MRC 600, or may be delivered as a result of a change in radio modem settings during transmission, as will be discussed with respect to synchronization below.

### VI. A Wireless Communication Device Including a Distributed Multiradio Control System.

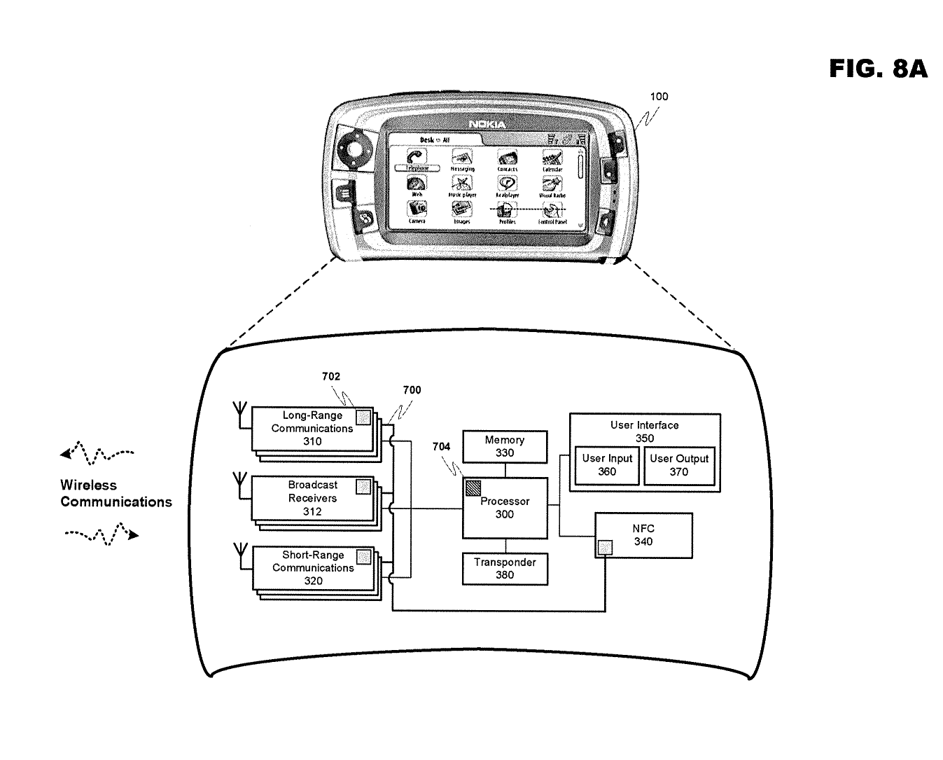

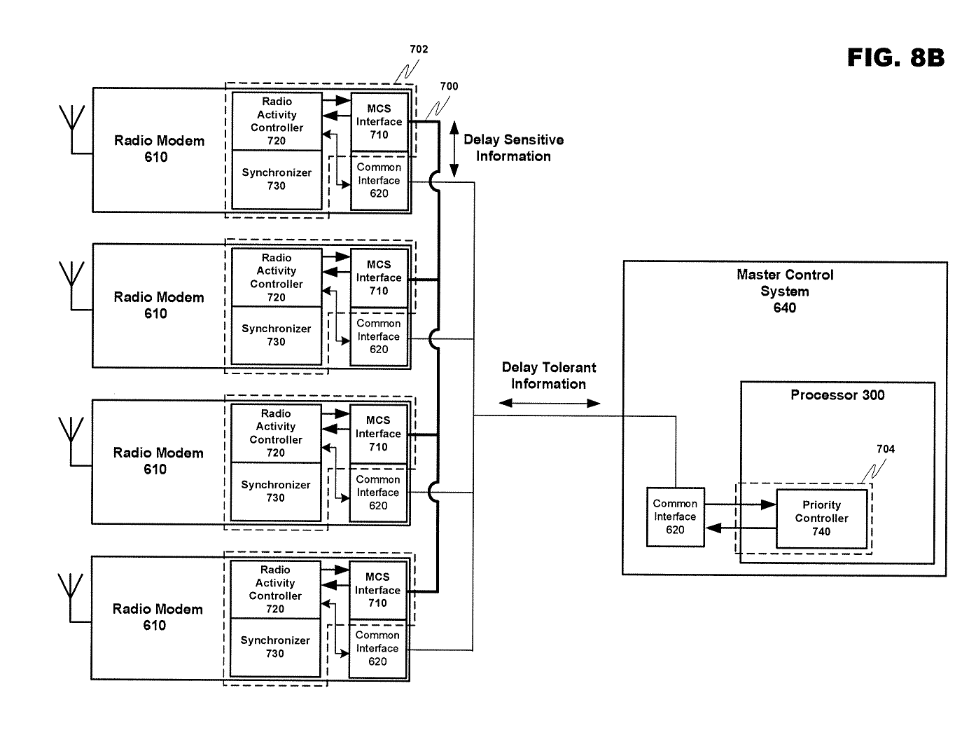

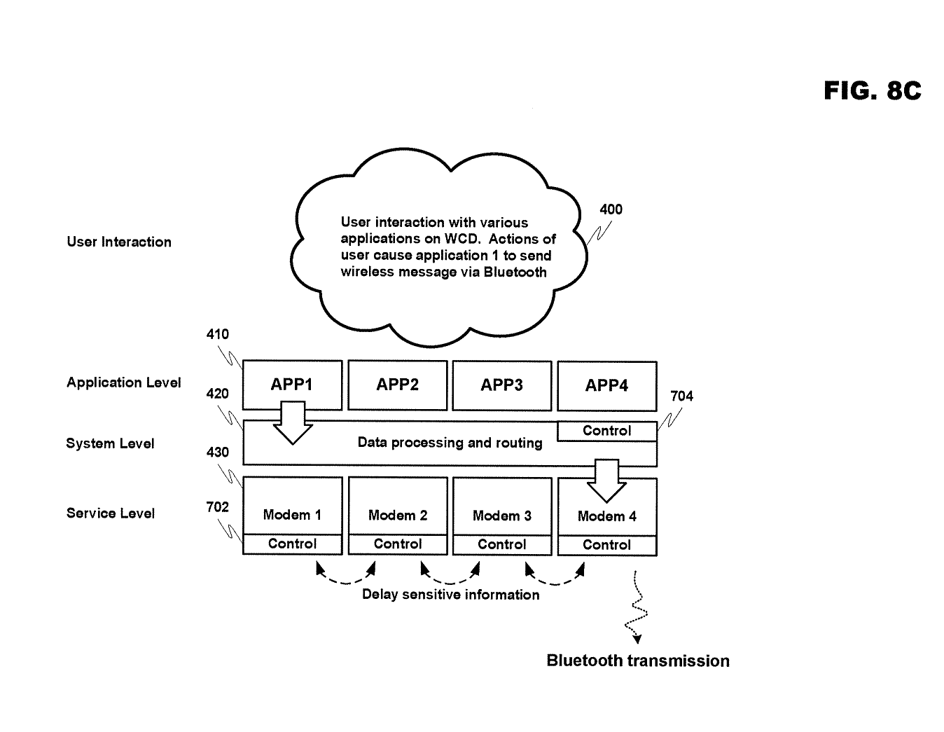

FIG. 8A discloses an alternative configuration in accordance with at least one embodiment of the present invention, wherein a distributed multiradio control system (MCS) 700 is introduced into WCD 100. Distributed MCS 700 may, in some cases, be deemed to provide an advantage over a centralized MRC 600 by distributing these control features into already necessary components within WCD 100. As a result, a substantial amount of the communication management operations may be localized to the various communication resources, such as radio modems 610, reducing the overall amount of control command traffic in WCD 100.

MCS 700, in this example, may be implemented utilizing a variety of bus structures, including the I²C interface commonly found in portable electronic devices, as well as emerging standards such as SLIMbus that are now under development. I²C is a multi-master bus, wherein multiple devices can be connected to the same bus and each one can act as a master through initiating a data transfer. An I²C bus contains at least two communication lines, an information line and a clock line. When a device has information to transmit, it assumes a master role and transmits both its clock signal and information to a recipient device. SLIMbus, on the other hand, utilizes a separate, non-differential physical layer that runs at rates of 50 Mbits/s or slower over just one lane. It is being developed by the Mobile Industry Processor Interface (MIPI) Alliance to replace today's I²C and I²S interfaces while offering more features and requiring the same or less power than the two combined.

MCS 700 directly links distributed control components 702 in modules 310, 312, 320 and 340. Another distributed control component 704 may reside in master control system 640 of WCD 100. It is important to note that distributed control component 704 shown in processor 300 is not limited only to this embodiment, and may reside in any appropriate system module within WCD 100. The addition of MCS 700 provides a dedicated low-traffic communication structure for carrying delay sensitive information both to and from the various distributed control components 702.

The exemplary embodiment disclosed in FIG. 8A is described with more detail in FIG. 8B. MCS 700 forms a direct link between distributed control components 702 within WCD 100. Distributed control components 702 in radio modems 610 may, for example, consist of MCS interface 710, radio activity controller 720 and synchronizer 730. Radio activity controller 720 uses MCS interface 710 to communicate with distributed control components in other radio modems 610. Synchronizer 730 may be utilized to obtain timing information from radio modem 610 to satisfy synchronization requests from any of the distributed control components 702. Radio activity controller 702 may also obtain information from master control system 640 (e.g., from distributed control component 704) through common interface 620. As a result, any information communicated by master control system 640 to radio activity controller 720 through common interface 620 may be deemed delay tolerant, and therefore, the actual arrival time of this information does not substantially influence communication system performance. On the other hand, all delay sensitive information may be conveyed by MCS 700, and therefore is insulated from master control system overloading.

As previously stated, a distributed control component 704 may exist within master control system 640. Some aspects of this component may reside in processor 300 as, for example, a running software routine that monitors and coordinates the behavior of radio activity controllers 720. Processor 300 is shown to contain priority controller 740. Priority controller 740 may be utilized to monitor active radio modems 610 in order to determine priority amongst these devices. Priority may be determined by rules and/or conditions stored in priority controller 740. Modems that become active may request priority information from priority controller 740. Further, modems that go inactive may notify priority controller 740 so that the relative priority of the remaining active radio modems 610 may be adjusted accordingly. Priority information is usually not considered delay sensitive because it is mainly updated when radio modems 610 activate/deactivate, and therefore, does not frequently change during the course of an active communication connection in radio modems 610. As a result, this information may be conveyed to radio modems 610 using common interface system 620 in at least one embodiment of the present invention.

At least one effect of a distributed control MCS 700 is seen in FIG. 8C. System level 420 may continue to provide delay tolerant information to distributed control components 702 through master control system 640. In addition, distributed control components 702 in service level 430, such as modem activity controllers 720, may exchange delay sensitive information with each other via MCS 700. Each distributed control component 702 may distinguish between these two classes of information and act accordingly. Delay tolerant information may include information that typically does not change when a radio modem is actively engaged in communication, such as radio mode information (e.g., GPRS, Bluetooth™, WLAN, etc.), priority information that may be defined by user settings, the specific service the radio is driving (QoS, real time/non real time), etc. Since delay tolerant information changes infrequently, it may be delivered in due course by master control system 640 of WCD 100. Alternatively, delay sensitive (or time sensitive) information may include at least modem operational information that frequently changes during the course of a wireless connection, and therefore, requires immediate update. Delay sensitive information needs to be delivered directly between distributed control components 702, and may include radio modem synchronization and activity control information. Delay sensitive information may be provided in response to a request, or may be delivered as a result of a change in radio modem, which will be discussed with respect to synchronization below.

MCS interface 710 may be used to (1) Exchange synchronization information, and (2) Transmit identification or prioritization information between various radio activity controllers 720. In addition, as previously stated, MCS interface 710 is used to communicate the radio parameters that are delay sensitive from a controlling point of view. MCS interface 710 can be shared between different radio modems (multipoint) but it cannot be shared with any other functionality that could limit the usage of MCS interface 710 from a latency point of view.

The control signals sent on MCS 700 that may enable/disable a radio modem 610 should be built on a modem's periodic events. Each radio activity controller 720 may obtain this information about a radio modem's periodic events from synchronizer 730. This kind of event can be, for example, frame clock event in GSM (4.615 ms), slot clock event in BT (625 us) or targeted beacon transmission time in WLAN (100 ms) or any multiple of these. A radio modem 610 may send its synchronization indications when (1) Any radio activity controller 720 requests it, (2) a radio modem internal time reference is changed (e.g. due to handover or handoff). The latency requirement for the synchronization signal is not critical as long as the delay is constant within a few microseconds. The fixed delays can be taken into account in the scheduling logic of radio activity controller 710.

The radio modem activity control is based on the knowledge of when the active radio modems 610 are about to transmit (or receive) in the specific connection mode in which the radios are currently operating. The connection mode of each radio modem 610 may be mapped to the time domain operation in their respective radio activity controller 720. As an example, for a GSM speech connection, priority controller 740 may have knowledge about all traffic patterns of GSM. This information may be transferred to the appropriate radio activity controller 720 when radio modem 610 becomes active, which may then recognize that the speech connection in GSM includes one transmission slot of length 577 μs, followed by an empty slot after which is the reception slot of 577 μs, two empty slots, monitoring (RX on), two empty slots, and then it repeats. Dual transfer mode means two transmission slots, empty slot, reception slot, empty slot, monitoring and two empty slots. When all traffic patterns that are known a priori by the radio activity controller 720, it only needs to know when the transmission slot occurs in time to gain knowledge of when the GSM radio modem is active. This information may be obtained by synchronizer 730. When the active radio modem 610 is about to transmit (or receive) it must check every time whether the modem activity control signal from its respective radio activity controller 720 permits the communication. Radio activity controller 720 is always either allowing or disabling the transmission of one full radio transmission block (e.g. GSM slot).

### VII. A Wireless Communication Device Including an Alternative Example of a Distributed Multiradio Control System.

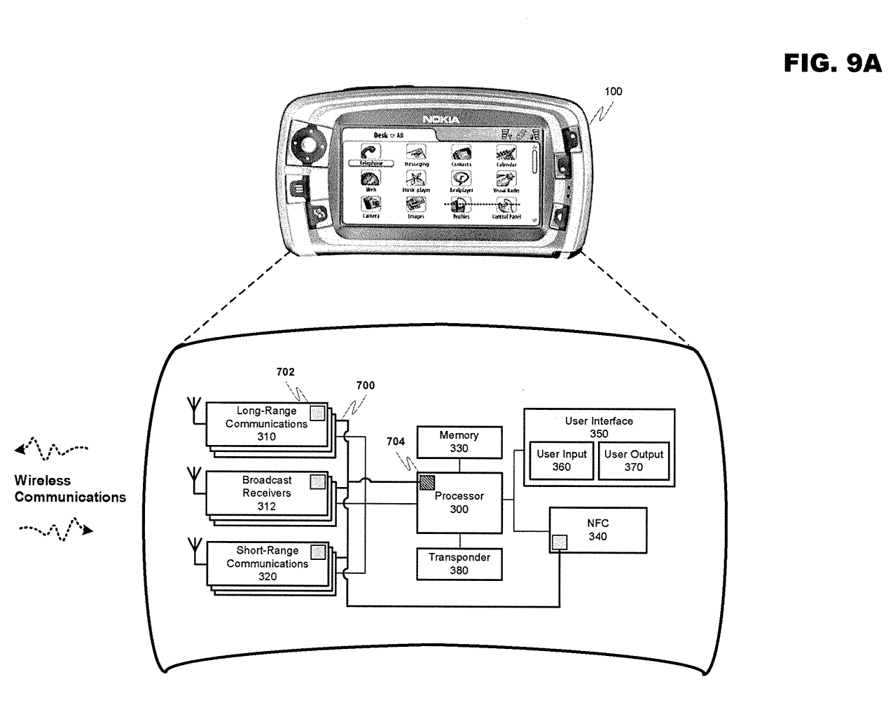

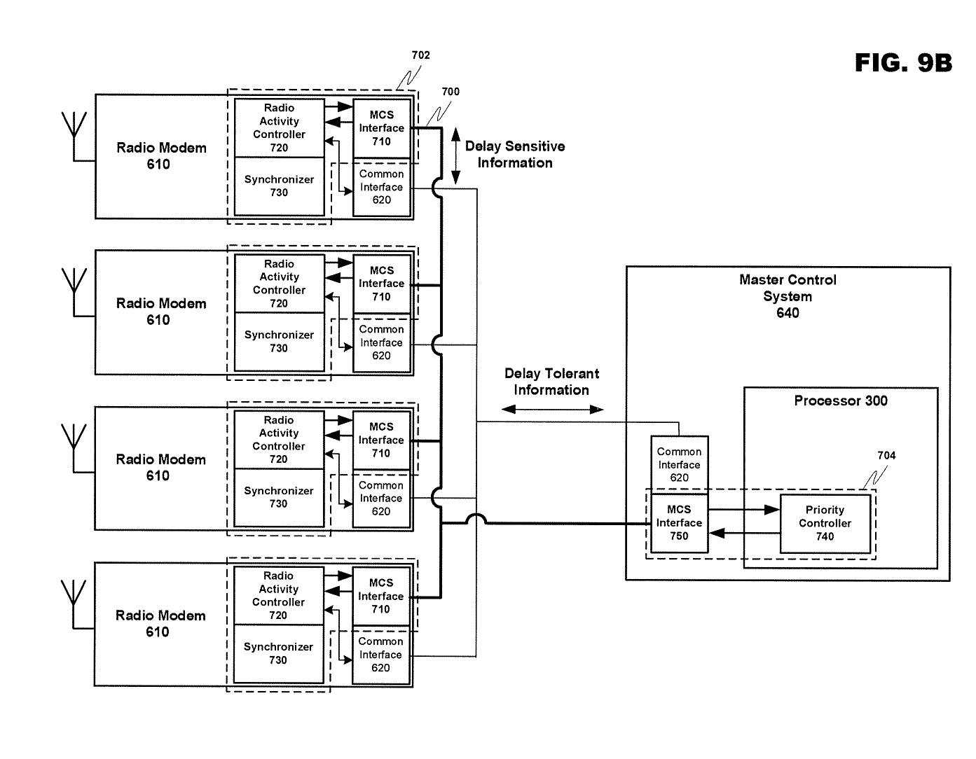

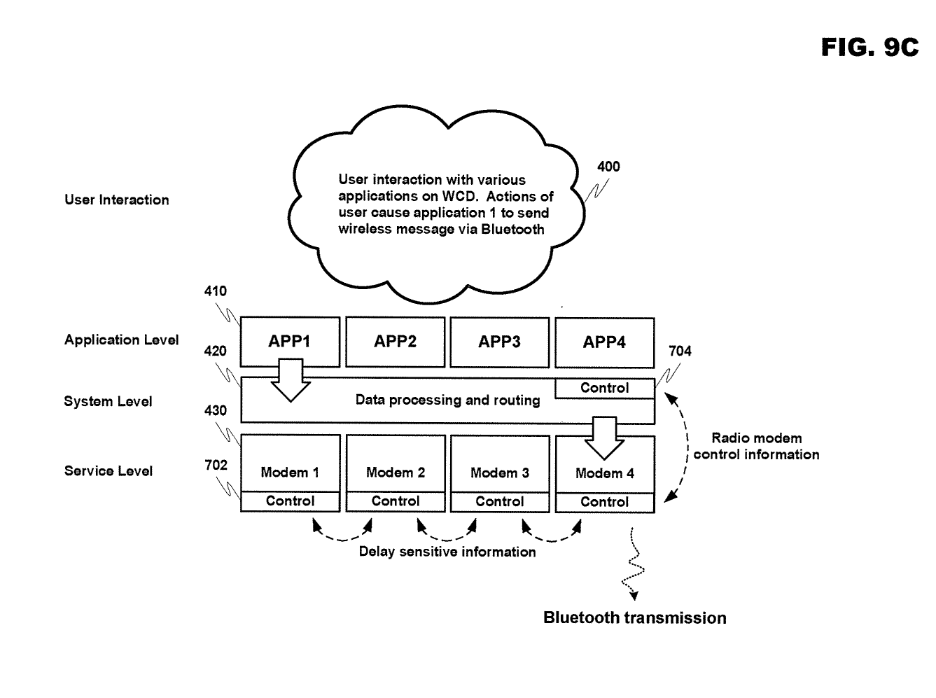

An alternative distributed control configuration in accordance with at least one embodiment of the present invention is disclosed in FIG. 9A-9C. In FIG. 9A, distributed control components 702 continue to be linked by MCS 700. However, now distributed control component 704 is also directly coupled to distributed control components 702 via an MCS interface. As a result, distributed control component 704 may also utilize and benefit from MCS 700 for transactions involving the various communication components of WCD 100.

Referring now to FIG. 9B, the inclusion of distributed control component 704 onto MCS 700 is shown in more detail. Distributed control component 704 includes at least priority controller 740 coupled to MCS interface 750. MCS interface 750 allows priority controller 740 to send information to, and receive information from, radio activity controllers 720 via a low-traffic connection dedicated to the coordination of communication resources in WCD 100. As previously stated, the information provided by priority controller 740 may not be deemed delay sensitive information, however, the provision of priority information to radio activity controllers 720 via MCS 700 may improve the overall communication efficiency of WCD 100. Performance may improve because quicker communication between distributed control components 702 and 704 may result in faster relative priority resolution in radio activity controllers 720. Further, the common interface system 620 of WCD 100 will be relieved of having to accommodate communication traffic from distributed control component 704, reducing the overall communication load in master control system 640. Another benefit may be realized in communication control flexibility in WCD 100. New features may be introduced into priority controller 740 without worrying about whether the messaging between control components will be delay tolerant or sensitive because an MCS interface 710 is already available at this location.

FIG. 9C discloses the operational effect of the enhancements seen in the current alternative embodiment of the present invention on communication in WCD 100. The addition of an alternative route for radio modem control information to flow between distributed control components 702 and 704 may both improve the communication management of radio activity controllers 720 and lessen the burden on master control system 640. In this embodiment, all distributed control components of MCS 700 are linked by a dedicated control interface, which provides immunity to communication coordination control messaging in WCD 100 when the master control system 640 is experiencing elevated transactional demands.

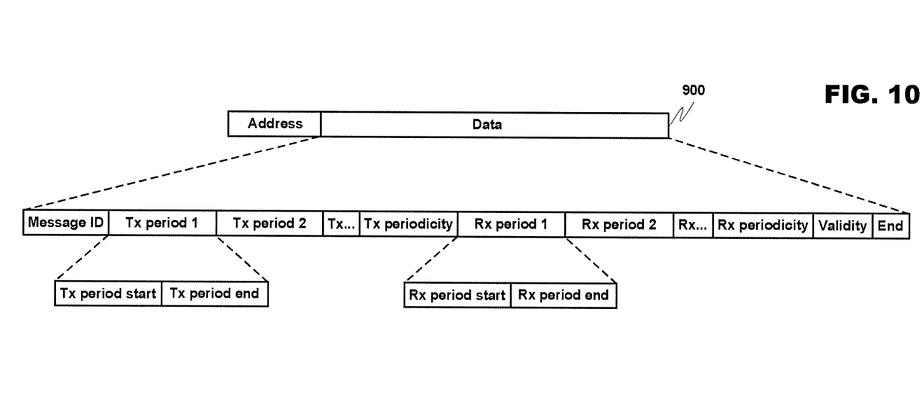

An example message packet 900 is disclosed in FIG. 10 in accordance with at least one embodiment of the present invention. Example message packet 900 includes activity pattern information that may be formulated by MRC 600 or radio activity controller 720. The data payload of packet 900 may include, in at least one embodiment of the present invention, at least Message ID information, allowed/disallowed transmission (Tx) period information, allowed/disallowed reception (Rx) period information, Tx/Rx periodicity (how often the Tx/Rx activities contained in the period information occur), and validity information describing when the activity pattern becomes valid and whether the new activity pattern is replacing or added to the existing one. The data payload of packet 900, as shown, may consist of multiple allowed/disallowed periods for transmission or reception (e.g., Tx period 1, 2 . . . ) each containing at least a period start time and a period end time during which radio modem 610 may either be permitted or prevented from executing a communication activity. While the distributed example of MCS 700 may allow radio modem control activity to be controlled real-time (e.g., more control messages with finer granularity), the ability to include multiple allowed/disallowed periods into a single message packet 900 may support radio activity controllers 720 in scheduling radio modem behavior for longer periods of time, which may result in a reduction in message traffic. Further, changes in radio modem 610 activity patterns may be amended using the validity information in each message packet 900.

The modem activity control signal (e.g., packet 900) may be formulated by MRC 600 or radio activity controller 720 and transmitted on MCS 700. The signal includes activity periods for Tx and Rx separately, and the periodicity of the activity for the radio modem 610. While the native radio modem clock is the controlling time domain (never overwritten), the time reference utilized in synchronizing the activity periods to current radio modem operation may be based on one of at least two standards. In a first example, a transmission period may start after a pre-defined amount of synchronization events have occurred in radio modem 610. Alternatively, all timing for MRC 600 or between distributed control components 702 may be standardized around the system clock for WCD 100. Advantages and disadvantages exist for both solutions. Using a defined number of modem synchronization events is beneficial because then all timing is closely aligned with the radio modem clock. However, this strategy may be more complicated to implement than basing timing on the system clock. On the other hand, while timing based on the system clock may be easier to implement as a standard, conversion to modem clock timing must necessarily be implemented whenever a new activity pattern is installed in radio modem 610.

The activity period may be indicated as start and stop times. If there is only one active connection, or if there is no need to schedule the active connections, the modem activity control signal may be set always on allowing the radio modems to operate without restriction. The radio modem 610 should check whether the transmission or reception is allowed before attempting actual communication. The activity end time can be used to check the synchronization. Once the radio modem 610 has ended the transaction (slot/packet/burst), it can check whether the activity signal is still set (it should be due to margins). If this is not the case, the radio modem 610 can initiate a new synchronization with MRC 600 or with radio activity controller 720 through synchronizer 730. The same happens if a radio modem time reference or connection mode changes. A problem may occur if radio activity controller 720 runs out of the modem synchronization and starts to apply modem transmission/reception restrictions at the wrong time. Due to this, modem synchronization signals need to be updated periodically. The more active wireless connections, the more accuracy is required in synchronization information.

### VIII. Radio Modem Interface to Other Devices.

As a part of information acquisition services, the MCS interface 710 needs to send information to MRC 600 (or radio activity controllers 720) about periodic events of the radio modems 610. Using its MCS interface 710, the radio modem 610 may indicate a time instance of a periodic event related to its operation. In practice these instances are times when radio modem 610 is active and may be preparing to communicate or communicating. Events occurring prior to or during a transmission or reception mode may be used as a time reference (e.g., in case of GSM, the frame edge may be indicated in a modem that is not necessarily transmitting or receiving at that moment, but we know based on the frame clock that the modem is going to transmit [x]ms after the frame clock edge). Basic principle for such timing indications is that the event is periodic in nature. Every incident needs not to be indicated, but the MRC 600 may calculate intermediate incidents itself. In order for that to be possible, the controller would also require other relevant information about the event, e.g. periodicity and duration. This information may be either embedded in the indication or the controller may get it by other means. Most importantly, these timing indications need to be such that the controller can acquire a radio modem's basic periodicity and timing. The timing of an event may either be in the indication itself, or it may be implicitly defined from the indication information by MRC 600 (or radio activity controller 720).

In general terms these timing indications need to be provided on periodic events like: schedule broadcasts from a base station (typically TDMA/MAC frame boundaries) and own periodic transmission or reception periods (typically Tx/Rx slots). Those notifications need to be issued by the radio modem 610: (1) on network entry (i.e. modem acquires network synchrony), (2) on periodic event timing change e.g. due to a handoff or handover and (3) as per the policy and configuration settings in the multiradio controller (monolithic or distributed).

In at least one embodiment of the present invention, the various messages exchanged between the aforementioned communication components in WCD 100 may be used to dictate behavior on both a local (radio modem level) and global (WCD level) basis. MRC 600 or radio activity controller 720 may deliver a schedule to radio modem 610 with the intent of controlling that specific modem, however, radio modem 610 may not be compelled to conform to this schedule. The basic principle is that radio modem 610 is not only operating according to multiradio control information (e.g., operates only when MRC 600 allows) but is also performing internal scheduling and link adaptation while taking MRC scheduling information into account.

### IX. Wake-Up Signals Utilized to Reactivate Components in a WCD.

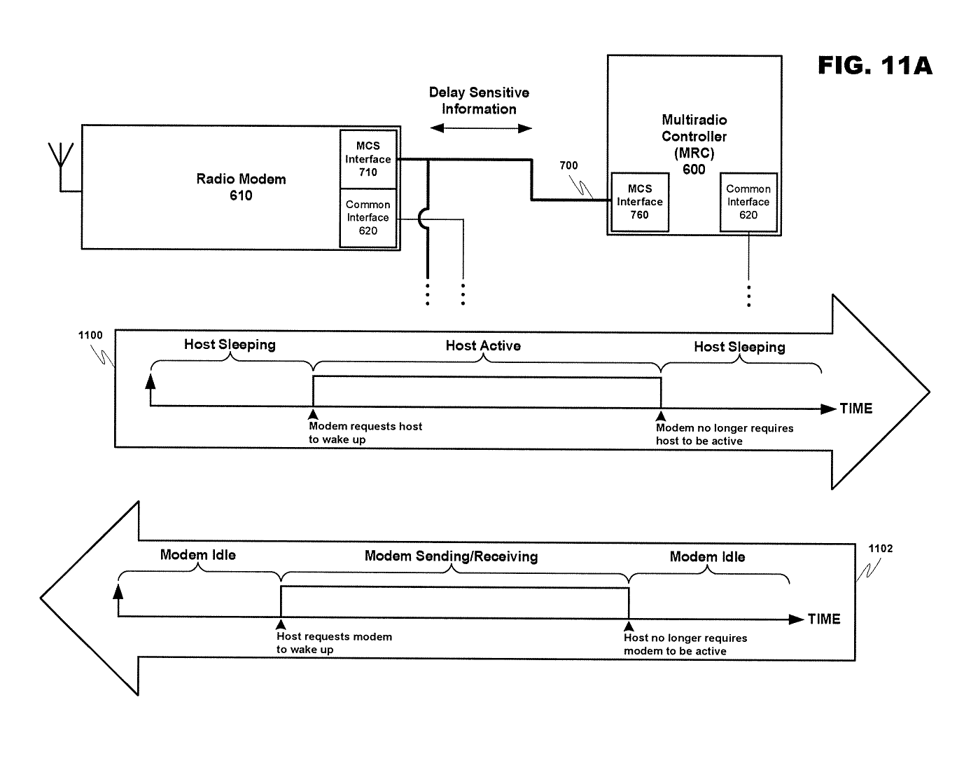

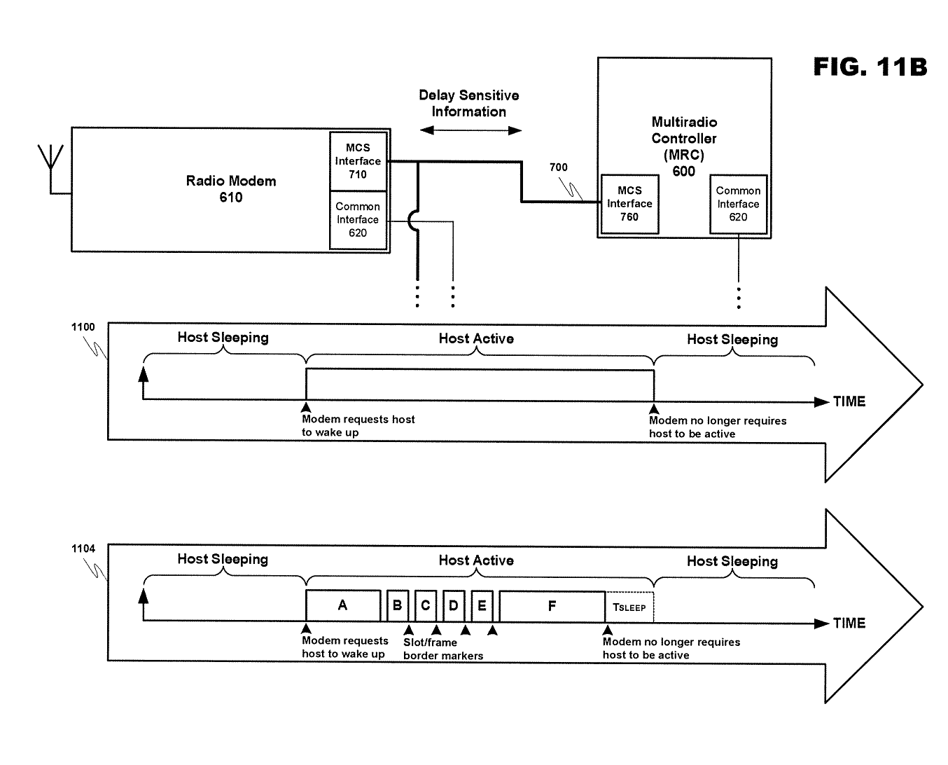

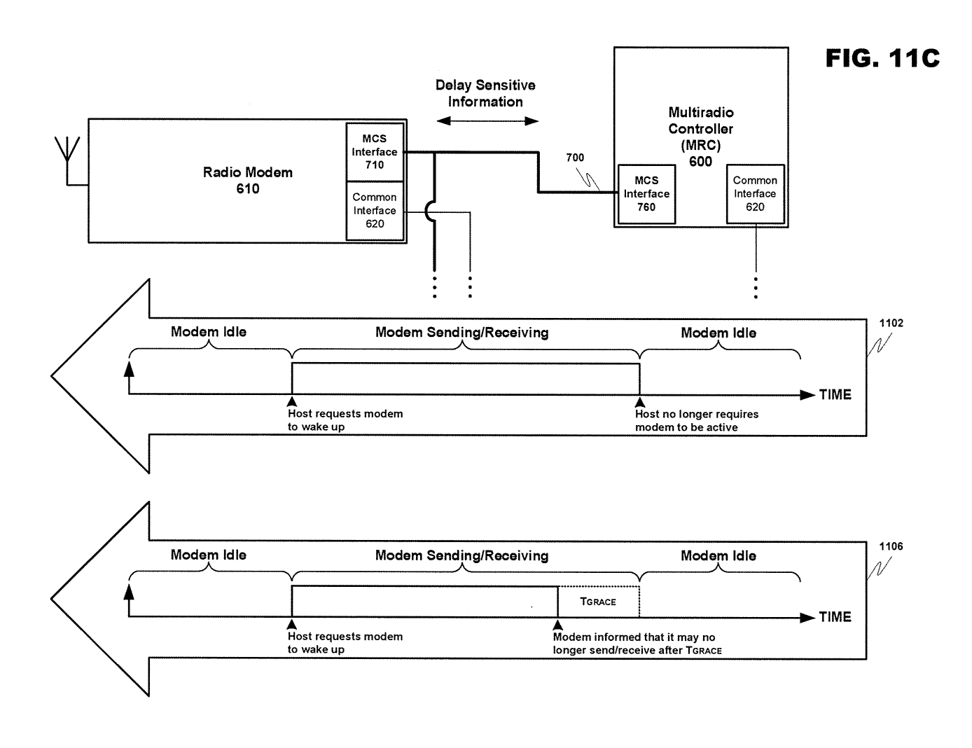

FIG. 11A discloses exemplary wake-up signals in accordance with at least one embodiment of the present invention. These signals may be utilized to trigger a mode change in a system component to which they are addressed. Two exemplary components that may exchange wake-up messages are shown in FIG. 11A. In at least one scenario, radio modem 610 may send wake-up signal 1100 to MRC 600 to inform MRC 600 about incoming wireless information or other events that may necessitate activity, and likewise, when information from WCD 100 is ready for wireless transmission, MRC 600 may issue wake-up signal 1102 to radio modem 610 in order to trigger a reactivation and allow radio modem 610 to prepare for sending wireless messages.

Additional detail concerning the timing and format of wake-up signals usable with the present invention is disclosed in FIG. 11A at 1100 and 1102. For example, a wake up signal 1100 issued from radio modem 610 may be monitored by various systems in WCD 100 including MRC 600. This signal may include a high signal pulse sustained over a variable duration. This high or energized signal, at its leading edge, may indicate to WCD 100 to change from one state (e.g., an inactive or sleep state) to another state (e.g., an active state). The wake-up signal issued by radio modem 610 may further include a part to notify MRC 600 of incoming wireless communication. The signal may remain high until radio modem 610 determines, for example, that no more wireless activity is pending. The signal may then transition from high to low, indicating to one or more WCD systems that they may return to their previous operating mode, which may have been an inactive or sleep mode in order to save power in WCD 100.

In the next example set forth in FIG. 11A, MRC 600 is issuing wake-up signal 1102. Again, wake-up signal 1102 may comprise a high signal pulse sustained over a variable duration. Wake-up signal 1102 may include parts that are generally usable in WCD 100 for system control, such as radio modem 610 sleep and active period control. In addition, wake-up signal 1102 may further include parts which are meant specifically for MRC 600 communication with radio modem 610. For example, while the signal pulse is high, radio modem 610 may be active and ready to receive message packets from applications in WCD 100 for transmission via a wireless medium. When wake-up signal 1102 goes low, WCD 100 and/or radio modem 610 may return to its previous operating mode, which may have been an inactive or sleep mode.

In addition, it is also possible to use wake-up signals in a scenario, for example, where many of the systems of WCD 100 are in sleep mode but radio modem 610 is still active in an energy-conserving low power state. Now wake-up signal 1102 may be utilized by MRC 600 to send signal control information to radio modem 610 during the sleep period. This control information may include, for example, scan activity control information used to control the activity of radio modem 610 during the sleep period.

These signals, as generally understood in the art, are primarily used for the purpose set forth above. If hard-coded in a microchip solution (e.g., ASIC, MCM, gate array, etc.) the wake-up features usually operate using at least one pin reserved for sending and possibly another pin used for receiving signals, and as a result, consume precious I/O resources in a microchip. Changing pin packages and redesigning microchips is an expensive proposition. As a result, the present invention avoids the need for hardware redesign as applied to at least one situation that may exist when managing a plurality of radio modems in a multiradio scheme.

### X. Wake-Up Signals

Now referring to FIG. 11B, both the previously described wake-up signal 1100 and a modified wake-up signal 1104 in accordance with at least one embodiment of the present invention are disclosed. Again, a wake-up signal may be utilized to trigger a mode change in a system component to which they are addressed. However, additional functionality may also be associated with the wake-up signal allowing synchronization or control information to be included within the wake-up signal.

An exemplary modified wake-up signal is shown at 1104. The signal is subdivided into high sections separated by low sections. These high-to-low transitions form leading and trailing edges in the signal that may be interpreted by MRC 600 in order to convey additional information. For the sake of explanation, the sections of wake-up signal 1104 have further been labeled “A”-“F” in FIG. 11B. Section A, for example, is the section of wake-up signal 1104 that indicates to MRC 600 that it should reactivate if currently in an inactive or sleep mode. As opposed to wake-up signal 1100 wherein the monitoring system component remains active as long as the signal is maintained high, section A of wake-up signal 1104 may operate as a start indicator of a predetermined duration. This predetermined duration in section A may, for example, indicate to MRC 600 that high to low transitions following section A (e.g., transitions following sections B-E) signify a slot/frame border markers. Markers B-E may be utilized, for example, in the synchronization of MRC 600 to the timing of radio modem 610. This timing may change, for example, when an inactive radio modem 610 reactivates and connects to a wireless network, and as a result, inherits the wireless network timing. The timing could also change if radio modem 610 changes the wireless medium with which it is communicating, if it experiences a handoff (handover) in a large wireless network due to the changing of the access point to which it is connected, etc. Therefore, when MRC 600 receives a signal pulse A of the predetermination duration of section A on its wake-up signal line, it may also be aware that high to low transitions from B-C, C-D, D-E and E-F signify slot/frame border markers that may be analyzed in order to synchronize MRC 600 to the timing of radio modem 610.

Section F of wake-up signal 1104 is a high period that may be of variable length. This section may stay active (high) as long as radio modem 610 senses incoming information that may require to attention of MRC 600. The high-to-low transition trailing section F may further indicate that radio modem 610 no longer requires MRC 600 to be active, and that MRC 600 may return to its previous operating mode, which may have been an inactive or sleep mode to save power in WCD 100.

As previously discussed in the example above, section A, sections B-E and section F may be differentiated based on signal pulse duration. For example, the predetermined signal may be the wake-up indicator (section A), which MRC 600 may interpret as a reactivation signal to be immediately followed by synchronization information (e.g., sections B-E). If the signal is longer than the predetermined time (section A), then it may be interpreted to be a deactivation signal, such as exemplary section F, which signifies that MRC 600 is no longer required by radio modem 610a. Other methods of identification may include alternative predetermined durations known to all system components. T_{SLEEP}, also indicated in FIG. 11B, may be used as a predetermined duration with which to compare the various pulses in wake-up signal 1104. Pulses that are shorter than T_{SLEEP} may be determined to be slot/frame border markers. Pulses longer than T_{SLEEP} may be considered a deactivation signal such as the exemplary section F. Wake-up section A may be identifiable because it will always be the first pulse signal following a deactivation section F. In this way, resynchronization may be triggered in MRC 600 any time pulses shorter than T_{SLEEP} are transmitted on the wake-up signal line.

FIG. 11C discloses an exemplary wake-up message from MRC 600 to radio modem 610 in accordance with at least one embodiment of the present invention. Wake-up signals 1102 and 1106 transmitted from MRC 600 to radio modem 612 are disclosed. In wake-up signal 1102, radio modem may become active from the time the leading edge of the high pulse but must deactivate at the trailing edge of the pulse. This sudden deactivation of radio modem 610 may break communication in the middle of message reception, causing the loss of message packets and requiring retransmission, which may impact the overall communication performance of WCD 100. However, wake-up signal 1106 includes additional functionality to help avoid this situation. T_{GRACE} may be a predetermined timeout known to both radio modem 610 and MRC 600 which allows radio modem 610 to complete transmission of information prior to deactivation. In this way, once the trailing edge of wake-up signal 1106 is sensed by radio modem 610, communication between radio modem 610 and other wireless devices may be concluded in an orderly manner before all communication is halted. Wake-up signal 1106 may indicate for radio modem 610 to become idle for various reasons, such as because the radio modem 610 is no longer needed, because MRC 600 is about to issue a new operational schedule, because another possibly conflicting radio modem 610 has an urgent message to send, etc.

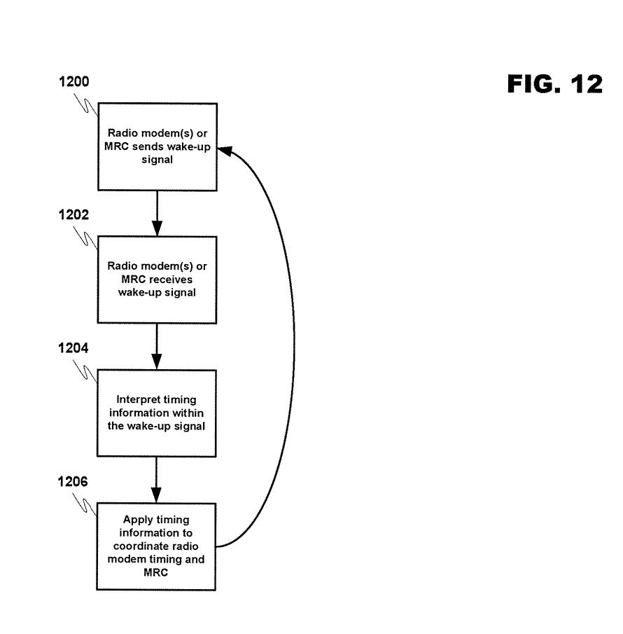

FIG. 12 discloses an exemplary process by which the previously set forth wake-up signals may be conveyed in accordance with at least one embodiment of the present invention. In step 1200 a system component (e.g., radio modem 610 or MRC 600) sends a wake-up message to another system component. This message is received in step 1202 and is interpreted in step 1203. The interpretation step may include, for example, monitoring of the pulses transmitted over a wake-up signal line in order to analyze various characteristics in the signal. Characteristics may include a leading edge of a pulse, a duration of a pulse, a trailing edge of a pulse, the order of the pulses, the number of pulses, etc. Once identified, these pulses may indicate synchronization and/or control information to the receiving system component. The synchronization and/or control information may be applied in step 1206 in order to alter the behavior of the receiving system component. The entire process may then begin again in step 1200 when the next wake-up signal is sent.

### XI. Alternative Communication Configuration.

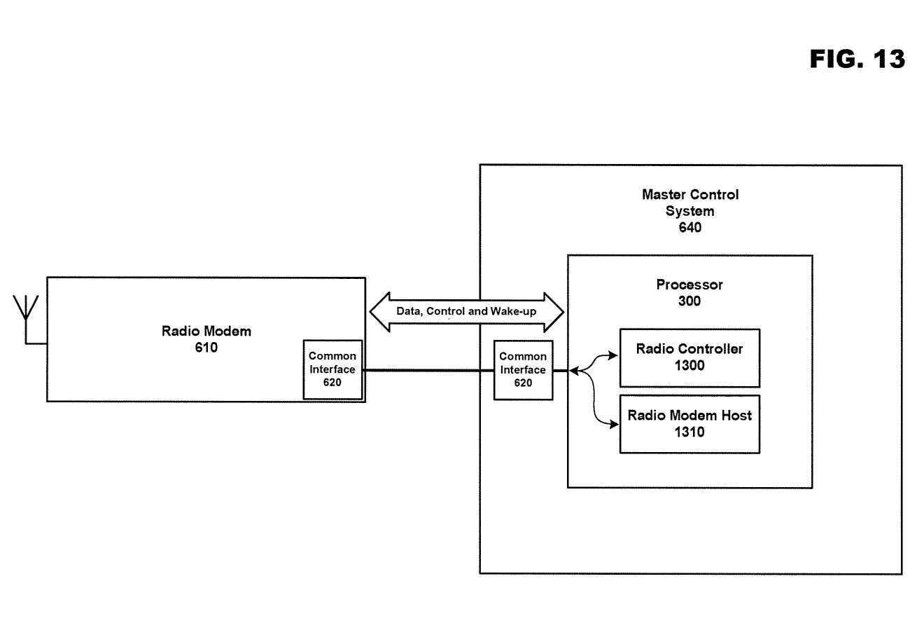

FIG. 13 discloses an alternative communication configuration in accordance with at least one embodiment of the present invention. It may still be possible to implement a form of the present invention in a WCD 100 that lacks the benefit of a dedicated MRC 600 or MCS 700, such as in a low cost or low complexity device. In FIG. 13, radio modem 610 may be coupled to a processing and/or control entity (e.g., processor 300) of WCD 100. This coupling may be made through master control system 640, and more specifically, through common interface 620.

The control entity in this scenario may be, for example, software programs stored in memory 330 and executed by processor 300. Alternatively, the control entity may be a hard-coded sub-element integrated into processor 300 or, in some instances, may not be a part of processor 300 at all, being instead coupled to processor 300 and/or main control system 340. The control entity may be composed of radio controller 1300 and radio modem host 1310. These control elements may work together to both control the basic functions of radio modem 610 and implement radio scheduling if necessary. To implement this control, one or both of radio controller 1300 and radio modem host 1310 may send and receive control and synchronization messages using any of the aforementioned wake-up signals. These wake-up signals may include, in addition to an activation signal, data and control information as disclosed in FIG. 11A-11C.

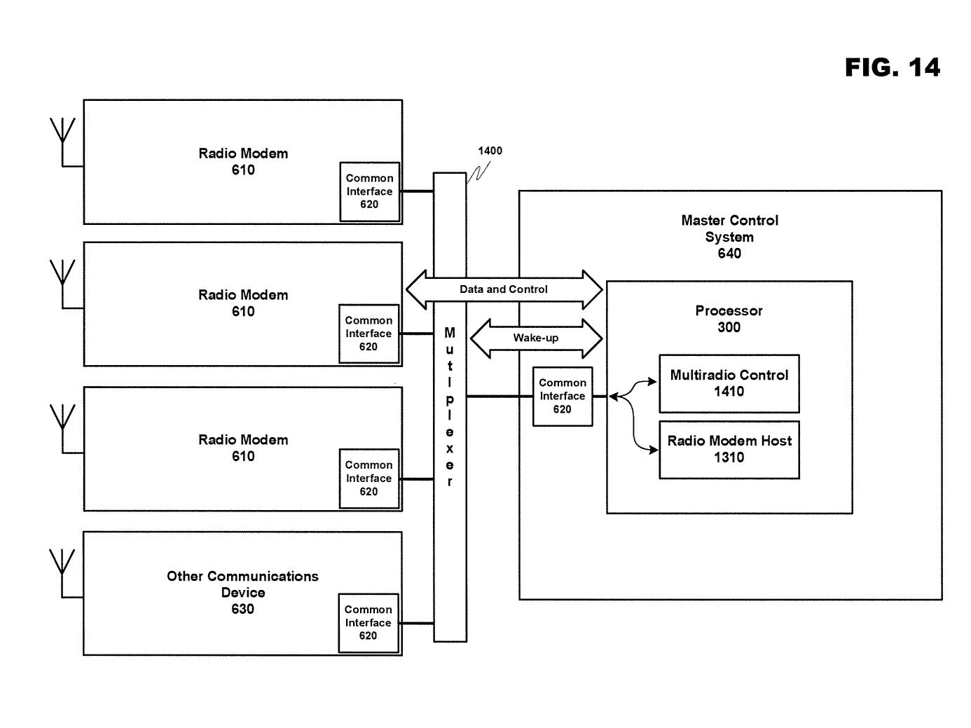

While a simplified configuration including at least one radio modem 610 is shown in FIG. 13, an implementation including a plurality of radio modems 610 is disclosed in FIG. 14. The plurality of radio modems 610 may be coupled to multiplexer 1400 that may be further coupled to processor 300 through master control system 640, and more specifically common interface 620. In this example, multiplexer 1400 may convey information from one or more of the plurality of radio modems 610 to at least multiradio control 1410 and/or radio modem host 1310 through interface 620, and conversely, may distribute information from at least these control entities back to each radio modem 610. Multiradio control 1410 and radio modem host 1310 may be similarly constituted as previously disclosed with regard to FIG. 13 above. These two control entities may work together to both control the basic functions of radio modems 610, as well as to implement radio modem scheduling in order to avoid potential communication conflicts between the plurality of radio modems 610.

Wake-up signals, in at least one scenario, may be directed to multiplexer 1400 from Multiradio control 1410 and/or radio modem host 1310. Multiplexer 1400 may then issue wake-up signals to one or more radio modems 610. The signal may be interpreted by radio modems 610 in order to implement control actions within the one or more radio modems 610 (e.g., the reactivation of radio modems 610). Further, when the radio modems 610 are active, data and control information may be issued from multiradio control 1410 and/or radio modem host 1310 in order to prepare these modems for wireless messages that may be queued for transmission in WCD 100. To implement the aforementioned control, one or both of multiradio control 1410 and radio modem host 1310 may send and receive control and synchronization messages using any of the aforementioned wake-up signals. These wake-up signals may include, in addition to an activation signal, data and control information as disclosed in FIG. 11A-11C.

The present invention provides at least one beneficial aspect over what is known in the art in that it may utilize existing hardware architectures to implement additional features in a multiradio device. The present invention allows a wake-up signal line, traditionally utilized mainly to transmit a simple reactivation signal, to be used for various additional tasks including synchronization and/or control functionality used to alter the behavior of a receiving device.

Accordingly, it will be apparent to persons skilled in the relevant art that various changes in form a and detail can be made therein without departing from the spirit and scope of the invention. This the breadth and scope of the present invention should not be limited by any of the above-described exemplary embodiments, but should be defined only in accordance with the following claims and their equivalents.

What is claimed:

1. A method, comprising:
receiving, in a multiradio controller, a signal relating to activity of one or more radio modems operating in a wireless network environment;
processing the signal received in the multiradio controller to interpret information contained in the received signal; and
utilizing the interpreted information to alter the behavior of the multiradio controller.

2. The method of claim 1, wherein the signal received by the multiradio controller is a wake-up signal transmitted by a radio modem contained in the same wireless communication device as the multiradio controller.

3. The method of claim 2, wherein the wake-up signal is used to change the multiradio controller from an inactive state to an active state.

4. The method of claim 1, wherein the information contained in the received signal is synchronization information.

5. The method of claim 4, wherein the synchronization information is related to slot/frame border markers for a wireless communication medium utilized by a radio modem contained in the same wireless communication device as the multiradio controller.

6. The method of claim 1, wherein the information contained in the received signal is control information.

7. The method of claim 6, wherein the control information indicates when the multiradio controller is required to operate and when the multiradio controller is no longer required to operate.

8. The method of claim 1, wherein utilizing the interpreted information includes at least one of synchronizing and controlling the multiradio controller based on information provided by a radio modem contained in the same wireless communication device.

9. A computer program product comprising a computer usable medium having computer readable program code embodied in said medium, comprising:
a computer readable program code for receiving, in a multiradio controller, a signal relating to activity of one or more radio modems operating in a wireless network environment;
a computer readable program code for processing the signal received in the multiradio controller to interpret information contained in the received signal; and
a computer readable program code for utilizing the interpreted information to alter the behavior of the multiradio controller.

10. The computer program product of claim 9, wherein the signal received by the multiradio controller is a wake-up signal transmitted by a radio modem contained in the same wireless communication device as the multiradio controller.

11. The computer program product of claim 10, wherein the wake-up signal is used to change the multiradio controller from an inactive state to an active state.

12. The computer program product of claim 9, wherein the information contained in the received signal is synchronization information.

13. The computer program product of claim 12, wherein the synchronization information is related to slot/frame border markers for a wireless communication medium utilized by a radio modem contained in the same wireless communication device as the multiradio controller.

14. The computer program product of claim 9, wherein the information contained in the received signal is control information.

15. The computer program product of claim 14, wherein the control information indicates when the multiradio controller is required to operate and when the multiradio controller is no longer required to operate.

16. The computer program product of claim 9, wherein utilizing the interpreted information includes at least one of synchronizing and controlling the multiradio controller based on information provided by a radio modem contained in the same wireless communication device.

17. A multiradio controller, comprising:
a communication module for receiving, in a multiradio controller, a signal relating to activity of one or more radio modems operating in a wireless network environment;
a computing module for processing the signal received in the multiradio controller to interpret information contained in the received signal, and utilizing the interpreted information to alter the behavior of the multiradio controller.

18. The controller of claim 17, wherein the signal received by the communication device is a wake-up signal transmitted by a radio modem contained in the same wireless communication device as the multiradio controller.

19. A method, comprising:
receiving, in one or more radio modems, a signal relating to activity of a controller;
processing the signal received in the one or more radio modems to interpret information contained in the received signal; and
utilizing the interpreted information to alter the behavior of the one or more radio modems.

20. The method of claim 19, wherein the signal received by the one or more radio modems is a wake-up signal transmitted by a multiradio controller contained in the same wireless communication device as the one or more radio modems.

21. The method of claim 20, wherein the wake-up signal is used to change the one or more radio modems from an inactive state to an active state.

22. The method of claim 19, wherein the information contained in the received signal is control information.

23. The method of claim 22, wherein the control information indicates when the one or more radio modems are required to operate and when the one or more radio modems must cease operation.

24. The method of claim 23, wherein the control information further includes a grace period during which the one or more radio modems conclude communication before operation must cease.

25. The method of claim 19, wherein utilizing the interpreted information includes controlling the one or more radio modems based on information provided by a multiradio controller contained in the same wireless communication device.

26. A computer program product comprising a computer usable medium having computer readable program code embodied in said medium, comprising:
a computer readable program code for receiving, in one or more radio modems, a signal relating to activity of a controller;
a computer readable program code for processing the signal received in the one or more radio modems to interpret information contained in the received signal; and
a computer readable program code for utilizing the interpreted information to alter the behavior of the one or more radio modems.

27. The computer program product of claim 26, wherein the signal received by the one or more radio modems is a wake-up signal transmitted by a multiradio controller contained in the same wireless communication device as the one or more radio modems.

28. The computer program product of claim 27, wherein the wake-up signal is used to change the one or more radio modems from an inactive state to an active state.

29. The computer program product of claim 26, wherein the information contained in the received signal is control information.

30. The computer program product of claim 29, wherein the control information indicates when the one or more radio modems are required to operate and when the one or more radio modems must cease operation.

31. The computer program product of claim 30, wherein the control information further includes a grace period during which the one or more radio modems conclude communication before operation must cease.

32. The computer program product of claim 26, wherein utilizing the interpreted information includes controlling the one or more radio modems based on information provided by a multiradio controller contained in the same wireless communication device.

33. A radio modem, comprising:
a communication module for receiving, in the radio modem, a signal relating to activity of a controller;
a computing module for processing the signal received in the radio modem to interpret information contained in the received signal, and utilizing the interpreted information to alter the behavior of the radio modem.

34. The modem of claim 33, wherein the signal received by the communication device is a wake-up signal transmitted by a multiradio controller contained in the same wireless communication device as the radio modem.

35. A data signal for providing interaction between one or more radio modems and a multiradio controller, comprising:
a communication signal including ON segments and OFF segments, wherein the ON segments are divided by the OFF segments;
wherein the multiradio controller is configured to alter its behavior based on the information of the received communication signal by interpreting one or more ON segments of the received communication signal as slot/frame border markers for synchronizing the timing of the multiradio controller to the timing of the one or more radio modems.
